(19) United States
(12) Patent Application Publication
(10) Pub. No.: US 2025/0380414 A1
(43) Pub. Date: Dec. 11, 2025

(54) THREE-DIMENSIONAL MEMORY CONTAINING ETCH-STOP ISOLATION CAPS OVER LATERAL ISOLATION STRUCTURES AND METHOD OF MAKING THE SAME

(71) Applicant: SANDISK TECHNOLOGIES LLC, ADDISON, TX (US)

(72) Inventors: Tomohiro OGINOE, Yokkaichi (JP); Masanori TSUTSUMI, Yokkaichi (JP); Junji OH, Yokkaichi (JP)

(21) Appl. No.: 18/771,091

(22) Filed: Jul. 12, 2024

Related U.S. Application Data
(60) Provisional application No. 63/658,175, filed on Jun. 10, 2024.

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80006; H01L 2224/80895; H01L 2224/80896; H01L 2924/1431; H01L 2924/14511

(57) ABSTRACT

A layer stack including a primary contact-level dielectric layer and a contact-level etch-stop dielectric layer over an assembly of an alternating stack of insulating layers and electrically conductive layers and memory opening fill structures. A lateral isolation structure is formed through the layer stack and a subset of the electrically conductive layers. An etch-stop isolation cap is formed over the lateral isolation structure. Drain contact via cavities are formed through at least the layer stack by performing an etch process that etches materials of the layer stack selective to the etch-stop isolation cap. Drain contact via structures are formed in the drain contact via cavities.

### FIELD

The present disclosure relates generally to the field of semiconductor devices, and particularly to a three-dimensional memory array including etch-stop isolation caps for lateral isolation structures and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: an alternating stack of insulating layers and electrically conductive layers; memory openings vertically extending through the alternating stack; memory opening fill structures located in the memory openings, wherein each of the memory opening fill structures comprises a respective vertical semiconductor channel, a respective vertical stack of memory elements, and a respective drain region; contact-level dielectric layers overlying the alternating stack; a lateral isolation structure vertically extending through a first subset of the electrically conductive layers within the alternating stack and a first subset of the contact-level dielectric layers; an etch-stop isolation cap overlying the lateral isolation structure; and drain contact via structures vertically extending through the contact-level dielectric layers and contacting top surfaces of the drain regions.

According to another aspect of the present disclosure, a method of forming a three-dimensional memory device is provided, which comprises: forming an assembly of an alternating stack and memory opening fill structures, wherein the alternating stack comprises a vertically alternating sequence of insulating layers and electrically conductive layers, the memory opening fill structures vertically extend through the alternating stack, and each of the memory opening fill structures comprises a respective vertical stack of memory elements, a respective vertical semiconductor channel, and a respective drain region; forming a layer stack including a primary contact-level dielectric layer and a contact-level etch-stop dielectric layer over the alternating stack; forming a lateral isolation structure through the layer stack and a subset of the electrically conductive layers; forming an etch-stop isolation cap over the lateral isolation structure; forming drain contact via cavities through at least the layer stack by performing an etch process that etches materials of the layer stack selective to the etch-stop isolation cap, wherein top surfaces of the drain regions are exposed underneath the drain contact via cavities; and forming drain contact via structures in the drain contact via cavities.

### BRIEF DESCRIPTION OF THE DRAWINGS

FIG. 1 is a schematic vertical cross-sectional view of a first exemplary structure after formation of an alternating stack of insulating layers and sacrificial material layers over a carrier substrate according to a first embodiment of the present disclosure.

FIG. 2 is a schematic vertical cross-sectional view of the first exemplary structure after formation of stepped surfaces and a stepped dielectric material portion according to the first embodiment of the present disclosure.

FIG. 3A is a schematic vertical cross-sectional view of the first exemplary structure after formation of memory openings and support openings according to the first embodiment of the present disclosure. FIG. 3B is a top-down view of the first exemplary structure of FIG. 3A. The hinged vertical cross-sectional plane A-A′ is the cut plane of the vertical cross-sectional view of FIG. 3A.

FIG. 4 is a schematic vertical cross-sectional view of the first exemplary structure after formation of sacrificial opening fill structures according to the first embodiment of the present disclosure.

FIG. 5 is a vertical cross-sectional view of the first exemplary structure after formation of support pillar structures according to the first embodiment of the present disclosure.

FIG. 6 is a schematic vertical cross-sectional view of the first exemplary structure after removal of sacrificial memory opening fill structures according to the first embodiment of the present disclosure.

FIGS. 7A-7F are sequential vertical cross-sectional views of a memory opening during formation of a memory opening fill structure according to the first embodiments of the present disclosure.

FIG. 8A is a schematic vertical cross-sectional view of the first exemplary structure after formation of memory opening fill structures according to the first embodiment of the present disclosure. FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of a layer stack including a contact-level etch-stop dielectric layer and a primary contact-level dielectric layer and lateral isolation trenches according to the first embodiment of the present disclosure. FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of laterally-extending cavities according to the first embodiment of the present disclosure.

FIG. 11 is a schematic vertical cross-sectional view of the first exemplary structure after formation of electrically conductive layers according to the first embodiment of the present disclosure.

FIG. 12 is a vertical cross-sectional view of the first exemplary structure after formation of lateral isolation trench fill structures according to the first embodiment of the present disclosure.

FIG. 13A is a vertical cross-sectional view of the first exemplary structure after formation of a hardmask layer, an optional pad layer, and lateral isolation cavities to the first embodiment of the present disclosure. FIG. 13B is a top-down view of the first exemplary structure of FIG. 13A. The hinged vertical cross-sectional plane A-A′ in FIG. 13B is the cut plane of the vertical cross-sectional view of FIG. 13A.

FIG. 14 is a vertical cross-sectional view of the first exemplary structure after formation of lateral isolation structures according to the first embodiment of the present disclosure.

FIG. 15 is a vertical cross-sectional view of the first exemplary structure after formation vertically recessing the lateral isolation structures according to the first embodiment of the present disclosure.

FIG. 16 is a vertical cross-sectional view of the first exemplary structure after removal of the hardmask layer according to the first embodiment of the present disclosure.

FIG. 17 is a vertical cross-sectional view of the first exemplary structure after deposition of an etch-stop cap material layer according to the first embodiment of the present disclosure.

FIG. 18 is a vertical cross-sectional view of the first exemplary structure after formation of etch-stop isolation caps according to the first embodiment of the present disclosure.

FIG. 19 is a vertical cross-sectional view of the first exemplary structure after formation of at least one contact-level dielectric capping layer according to the first embodiment of the present disclosure.

FIG. 20A is a vertical cross-sectional view of the first exemplary structure after a first step of an anisotropic etch process that etches unmasked portions of the at least one contact-level dielectric capping layer according to the first embodiment of the present disclosure. FIG. 20B is a top-down view of the first exemplary structure of FIG. 20A. The vertical plane A-A is the cut plane of the vertical cross-sectional view of FIG. 20A.

FIG. 21 is a vertical cross-sectional view of the first exemplary structure after a second step of an anisotropic etch process that etches unmasked portions of the primary contact-level dielectric layer according to the first embodiment of the present disclosure.

FIG. 22 is a vertical cross-sectional view of the first exemplary structure after a third step of an anisotropic etch process that etches unmasked portions of the contact-level etch-stop dielectric layer according to the first embodiment of the present disclosure.

FIG. 23A is a vertical cross-sectional view of the first exemplary structure after formation of layer contact via cavities according to the first embodiment of the present disclosure. FIG. 23B is a top-down view of the first exemplary structure of FIG. 23A. The vertical plane A-A is the cut plane of the vertical cross-sectional view of FIG. 23A.

FIG. 24A is a vertical cross-sectional view of the first exemplary structure after formation of drain contact via structures and layer contact via structures according to the first embodiment of the present disclosure. FIG. 24B is a top-down view of the first exemplary structure of FIG. 24A. The vertical plane A-A is the cut plane of the vertical cross-sectional view of FIG. 24A.

FIG. 25 is a vertical cross-sectional view of the first exemplary structure after formation of a memory die according to the first embodiment of the present disclosure.

FIG. 26 is a vertical cross-sectional view of a logic die according to the first embodiment of the present disclosure.

FIG. 27 is a vertical cross-sectional view of the first exemplary structure after attaching the logic die to the memory die according to the first embodiment of the present disclosure.

FIG. 28 is a vertical cross-sectional view of the first exemplary structure after removal of the carrier substrate and formation of a source layer and backside contact structures according to the first embodiment of the present disclosure.

FIG. 29 is a vertical cross-sectional view of a second exemplary structure after formation of in-process contact-level dielectric material layer according to the second embodiment of the present disclosure.

FIG. 30 is a vertical cross-sectional view of the second exemplary structure after replacement of sacrificial material layers with electrically conductive layers and after formation of lateral isolation trench fill structures according to the second embodiment of the present disclosure.

FIG. 31 is a vertical cross-sectional view of the second exemplary structure after formation of a layer stack including a primary contact-level dielectric layer and a contact-level etch-stop dielectric layer according to the second embodiment of the present disclosure.

FIG. 32A is a vertical cross-sectional view of the second exemplary structure after formation of lateral isolation cavities according to the second embodiment of the present disclosure. FIG. 32B is a top-down view of the second exemplary structure of FIG. 32A. The vertical plane A-A is the cut plane of the vertical cross-sectional view of FIG. 32A.

FIG. 33 is a vertical cross-sectional view of the second exemplary structure after formation of lateral isolation structures according to the second embodiment of the present disclosure.

FIG. 34 is a vertical cross-sectional view of the second exemplary structure after formation vertically recessing the lateral isolation structures according to the second embodiment of the present disclosure.

FIG. 35 is a vertical cross-sectional view of the second exemplary structure after deposition of an etch-stop cap material layer according to the second embodiment of the present disclosure.

FIG. 36 is a vertical cross-sectional view of the second exemplary structure after formation of etch-stop isolation caps according to the second embodiment of the present disclosure.

FIG. 37 is a vertical cross-sectional view of the second exemplary structure after formation of at least one contact-level dielectric capping layer according to the second embodiment of the present disclosure.

FIG. 38A is a vertical cross-sectional view of the second exemplary structure after a first step of an anisotropic etch process that etches unmasked portions of the at least one contact-level dielectric capping layer according to the second embodiment of the present disclosure. FIG. 38B is a horizontal cross-sectional view of a region of the second exemplary structure along the horizontal planes B-B′ in FIG. 38A.

FIG. 39 is a vertical cross-sectional view of the second exemplary structure after a terminal step of an anisotropic etch process that etches unmasked portions of the contact-level etch-stop dielectric layer and the primary contact-level dielectric layer according to the second embodiment of the present disclosure.

FIG. 40A is a vertical cross-sectional view of the second exemplary structure after formation of layer contact via cavities according to the second embodiment of the present disclosure. FIG. 40B is a horizontal cross-sectional view of a region of the second exemplary structure along the horizontal planes B-B′ in FIG. 40A.

FIG. 41A is a vertical cross-sectional view of the second exemplary structure after formation of drain contact via structures and layer contact via structures according to the second embodiment of the present disclosure. FIG. 41B is a horizontal cross-sectional view of a region of the second exemplary structure along the horizontal planes B-B′ in FIG. 41A.

FIG. 42 is a vertical cross-sectional view of the second exemplary structure after formation of a memory die, bonding the logic die to the memory die, removal of the carrier substrate, and formation of a source layer and backside contact structures according to the second embodiment of the present disclosure.

### DETAILED DESCRIPTION

Embodiments of the present disclosure are directed to a three-dimensional memory device including etch-stop isolation caps located over lateral isolation structures and methods for manufacturing the same. Embodiments of the disclosure can be employed to form various structures including a three-dimensional memory structure, non-limiting examples of which include three-dimensional NAND memory devices.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

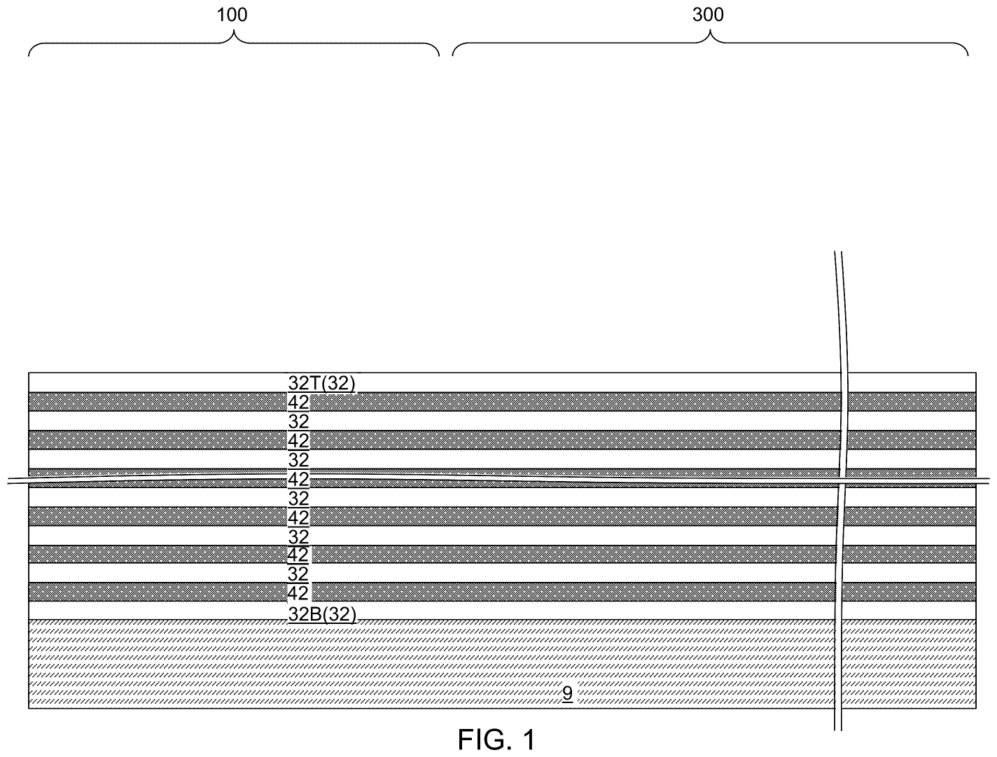

Referring to FIG. 1, a first exemplary structure according to the first embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective to the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 (i.e., an insulating layer 32 that is most proximal to the carrier substrate 9) is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

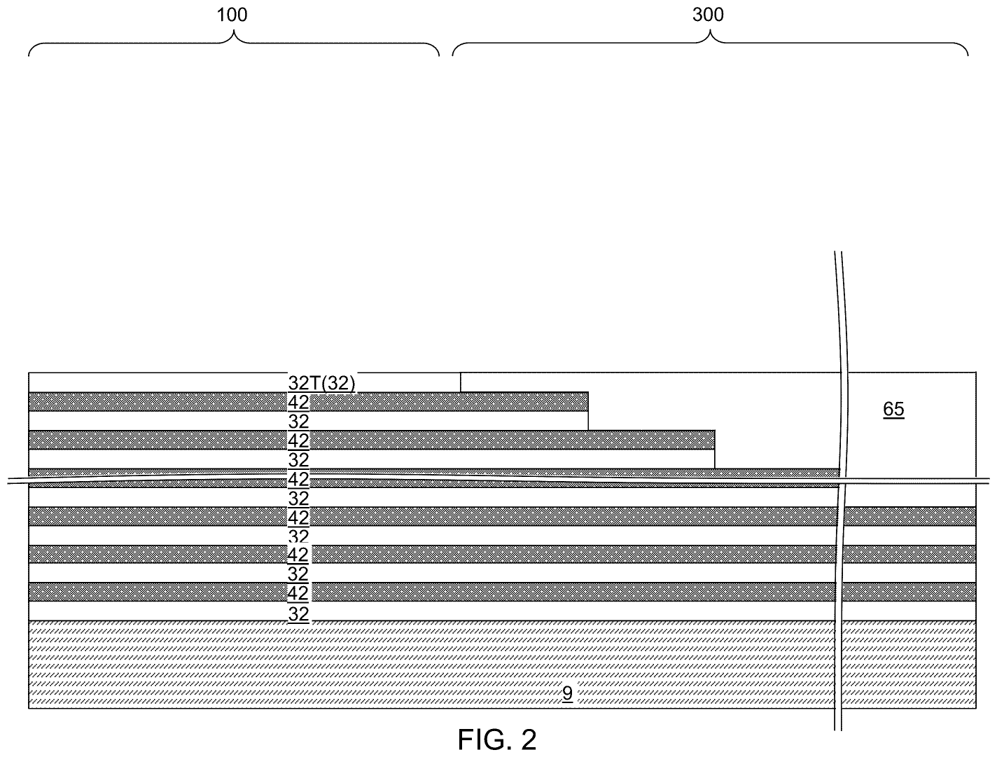

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

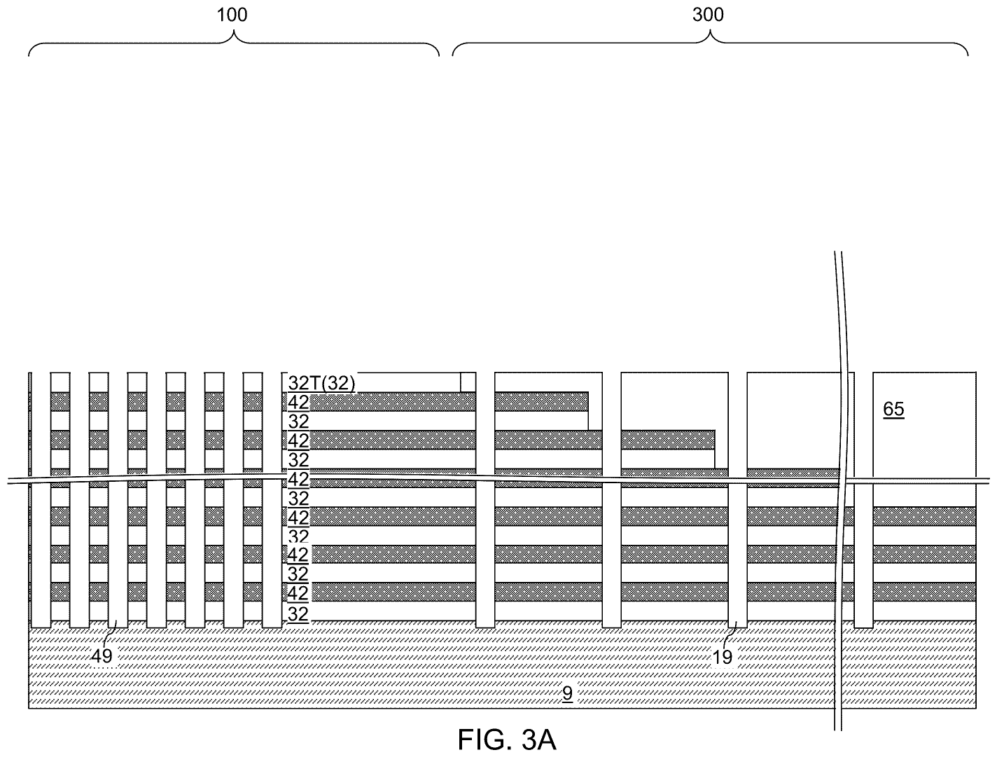

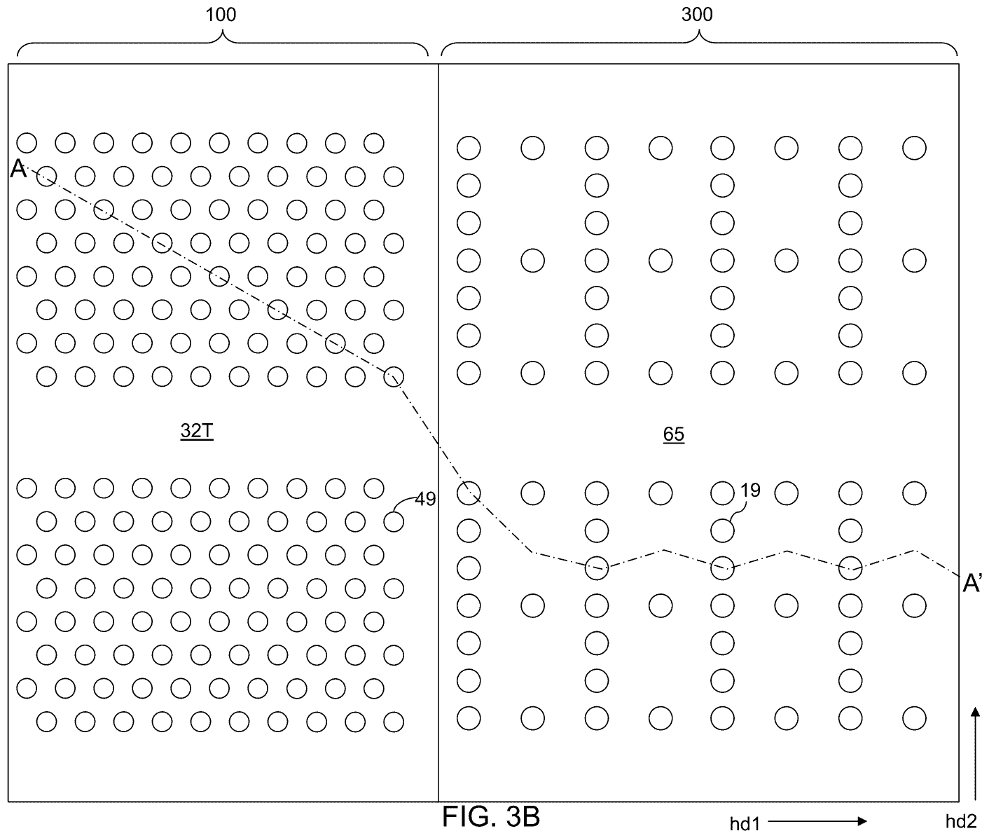

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater diameters may be employed. The support openings 19 may have a diameter in a range from 60 nm to 400 nm, such as from 120 nm to 300 nm, although lesser and greater diameters may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (which may be a word line direction) with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

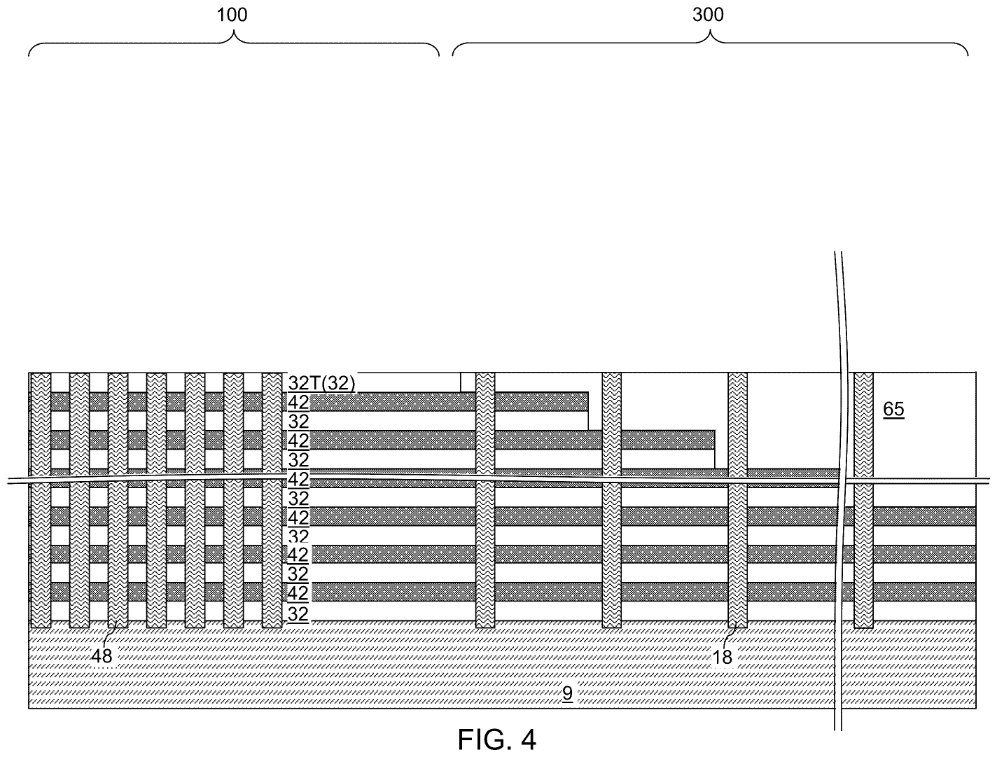

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

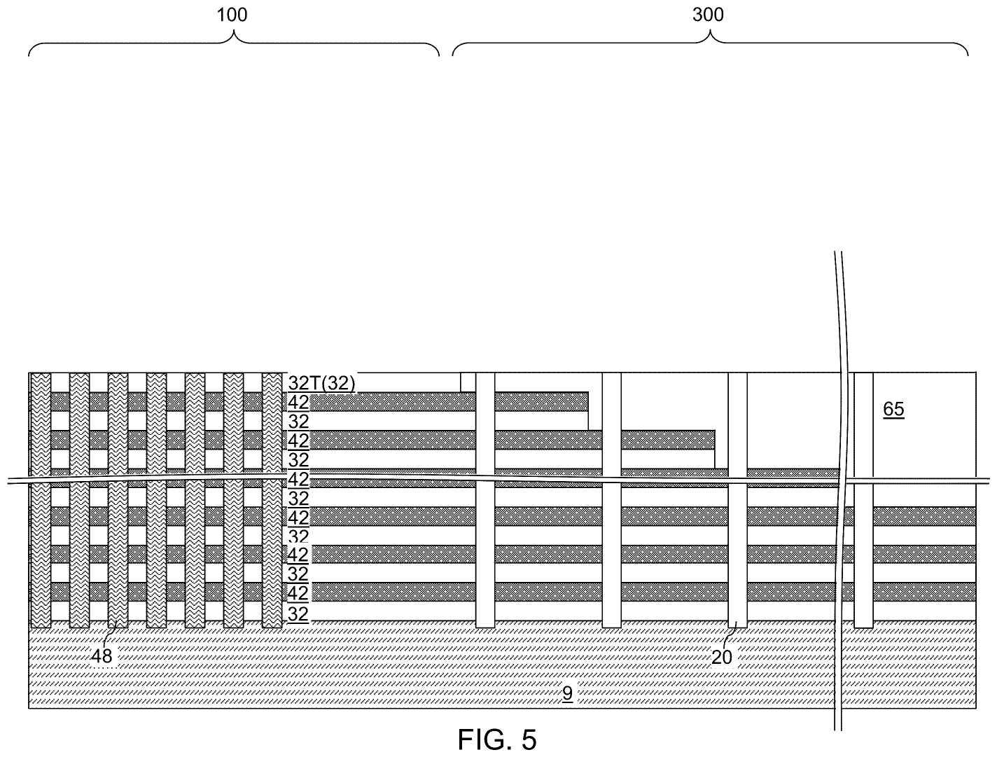

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

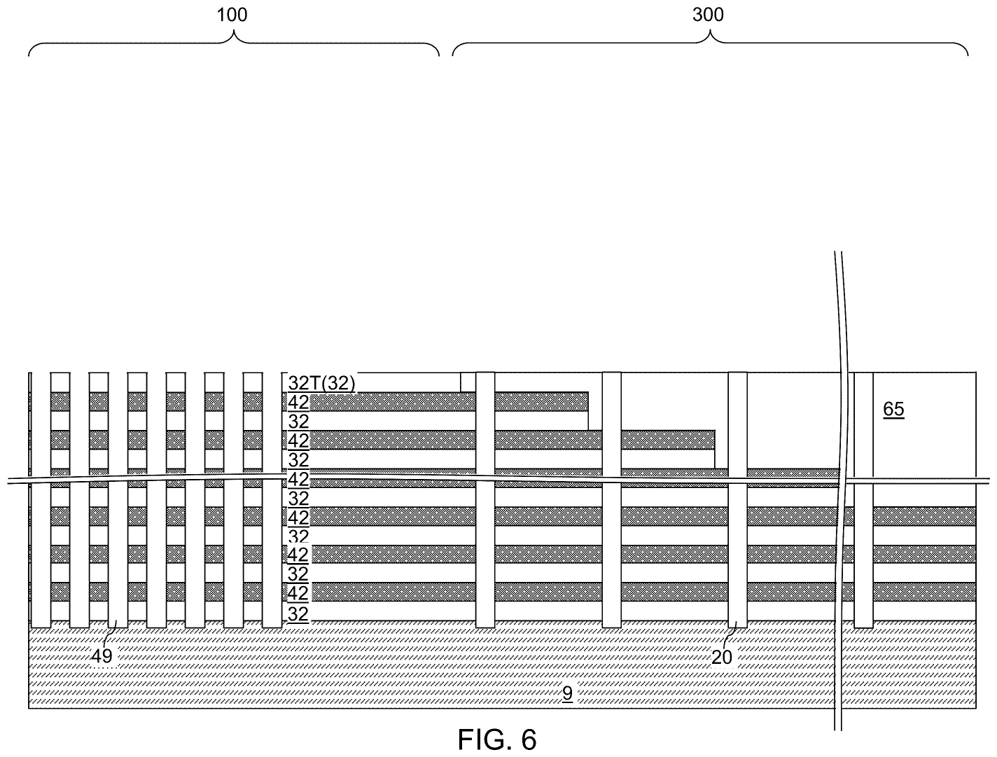

Referring to FIG. 6, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

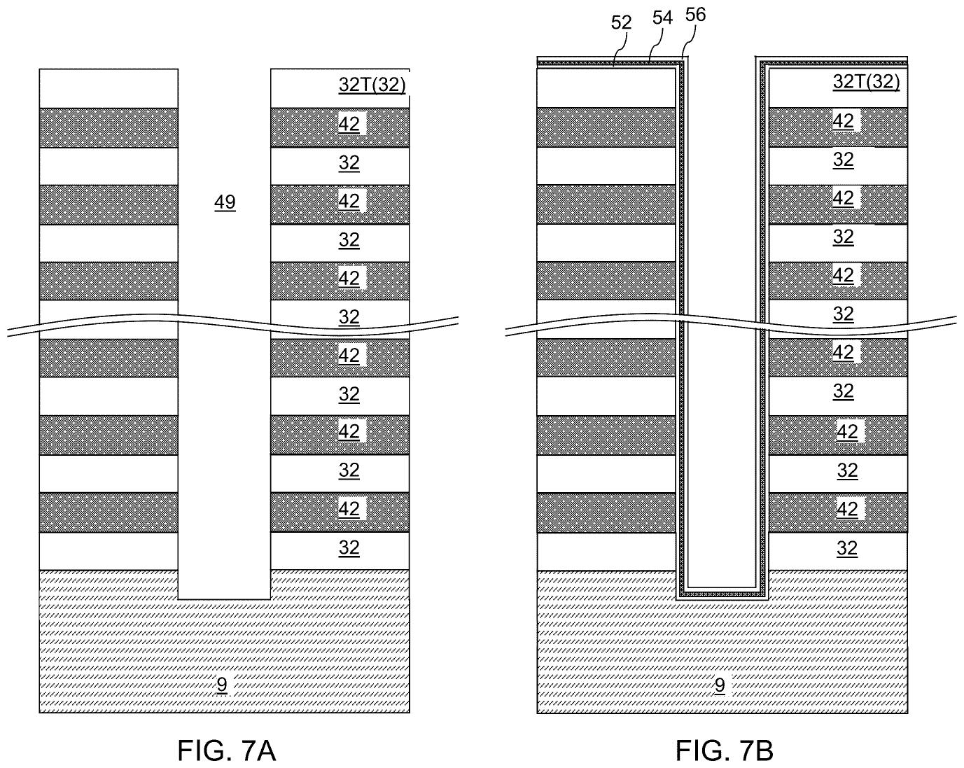

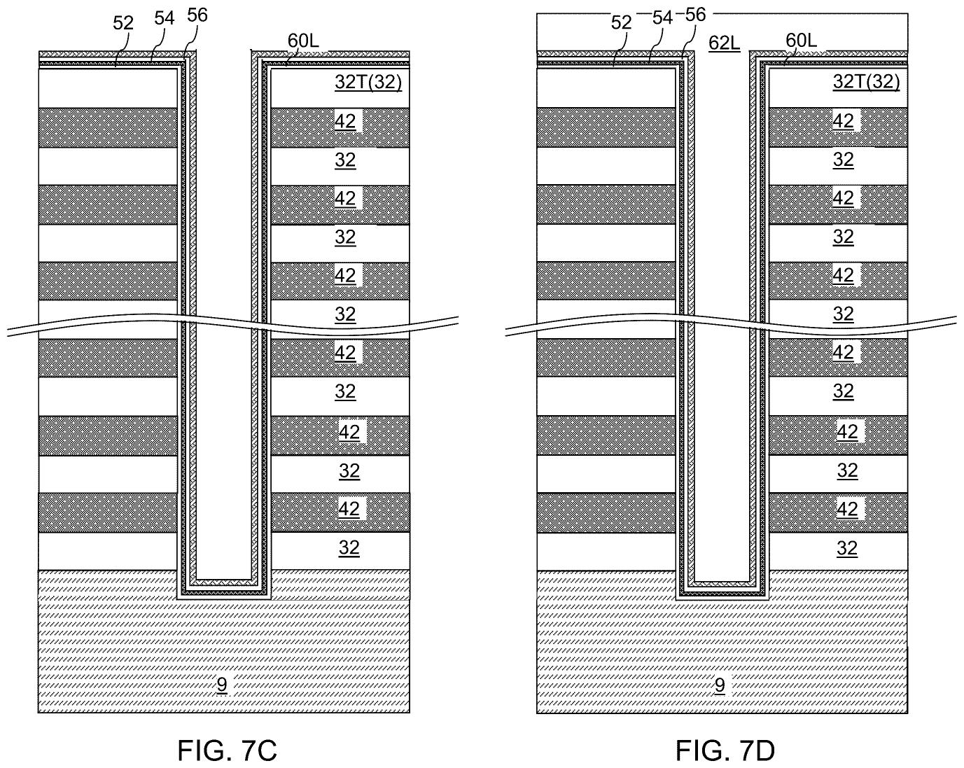

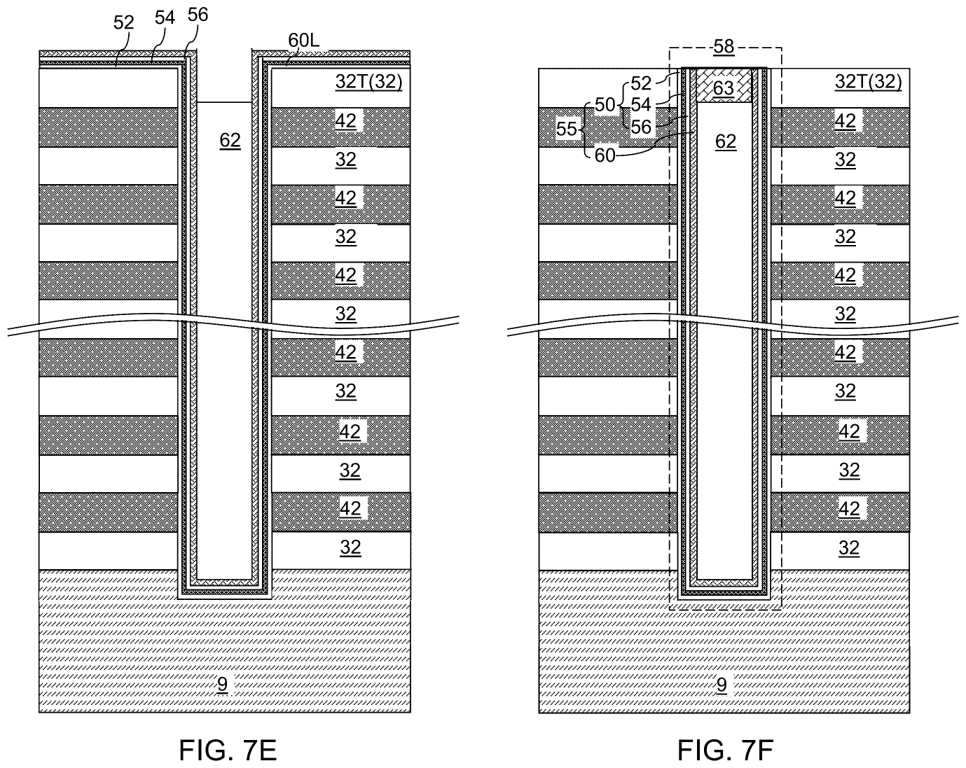

FIGS. 7A-7F are sequential vertical cross-sectional views of a memory opening 49 during formation of a memory opening fill structure 58 according to an embodiment of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. The dielectric core layer 62L can be deposited employing a conformal deposition process, such as a chemical vapor deposition process.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

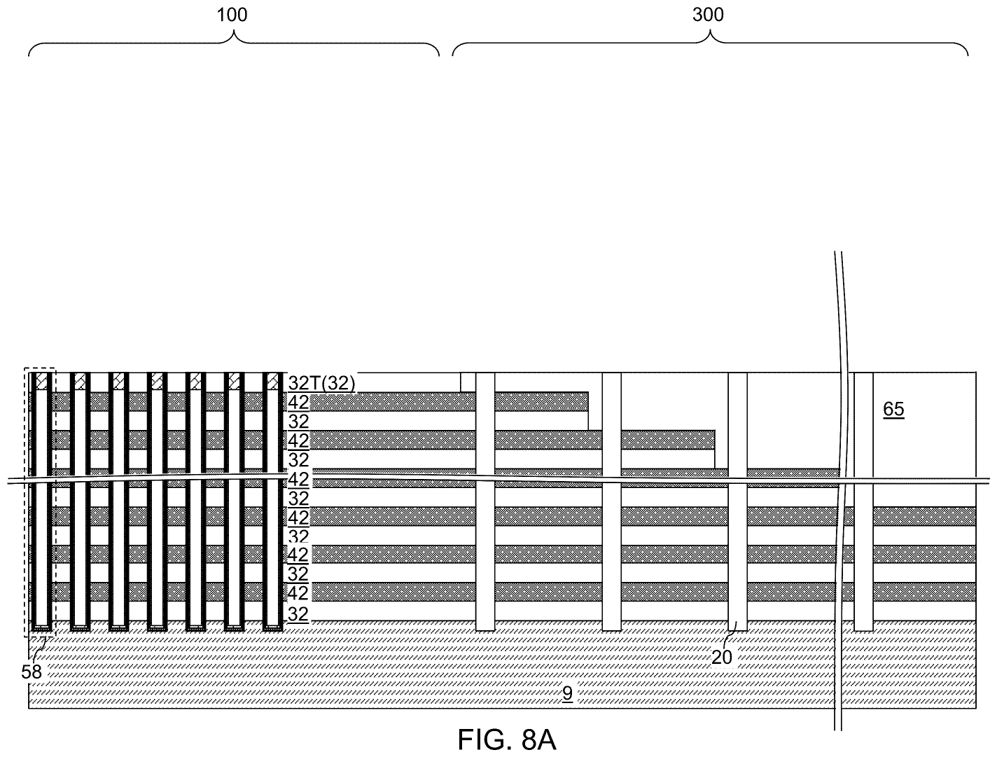

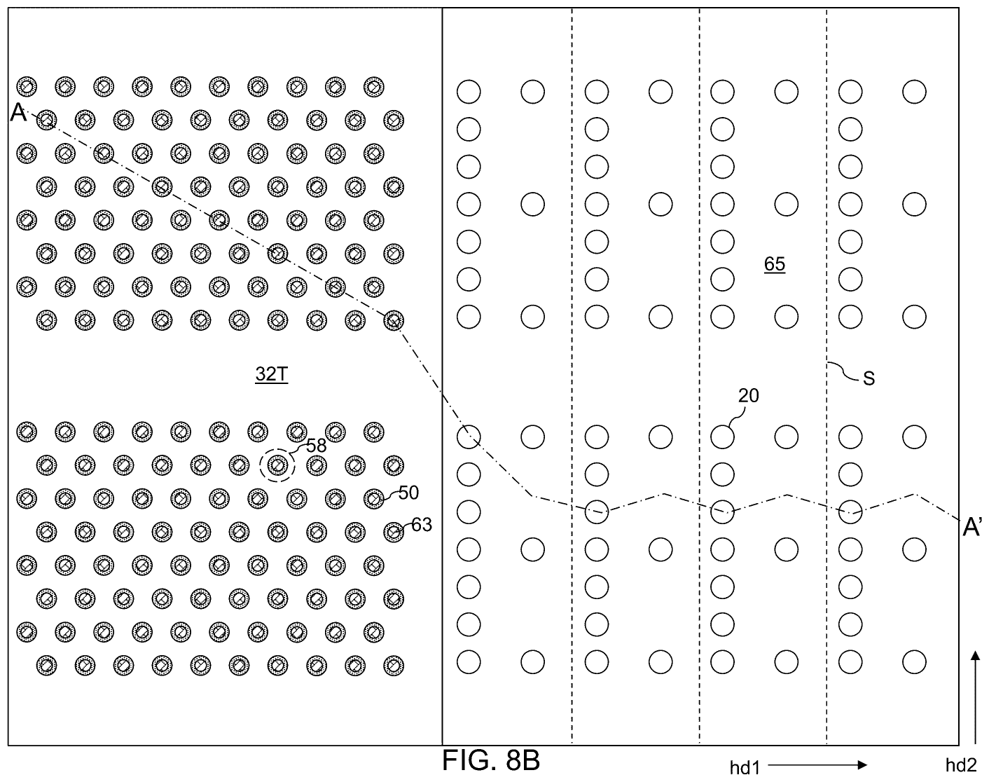

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

Thus, an alternating stack (32, 42) of insulating layers 32 and sacrificial material layers 42 is formed over a substrate (such as a carrier substrate 9). The spacer material layers are formed as or are subsequently replaced with electrically conductive layers. Memory openings 49 are formed through the alternating stack (32, 42). Memory opening fill structures 58 are formed in the memory openings 49. Each of the memory opening fill structures 58 comprises a respective memory film 50 and a respective vertical semiconductor channel 60 that is laterally surrounded by the respective memory film 50. The memory opening fill structures 58 are arranged in rows laterally extending along a first horizontal direction hd1, and the rows are laterally spaced apart from each other along a second horizontal direction hd2 that is perpendicular to the first horizontal direction hd1. Each of the memory opening fill structures 58 comprises a vertical stack of memory elements (which may comprise portions of a memory film 50 located at levels of the sacrificial material layers 42), and a respective drain region 63.

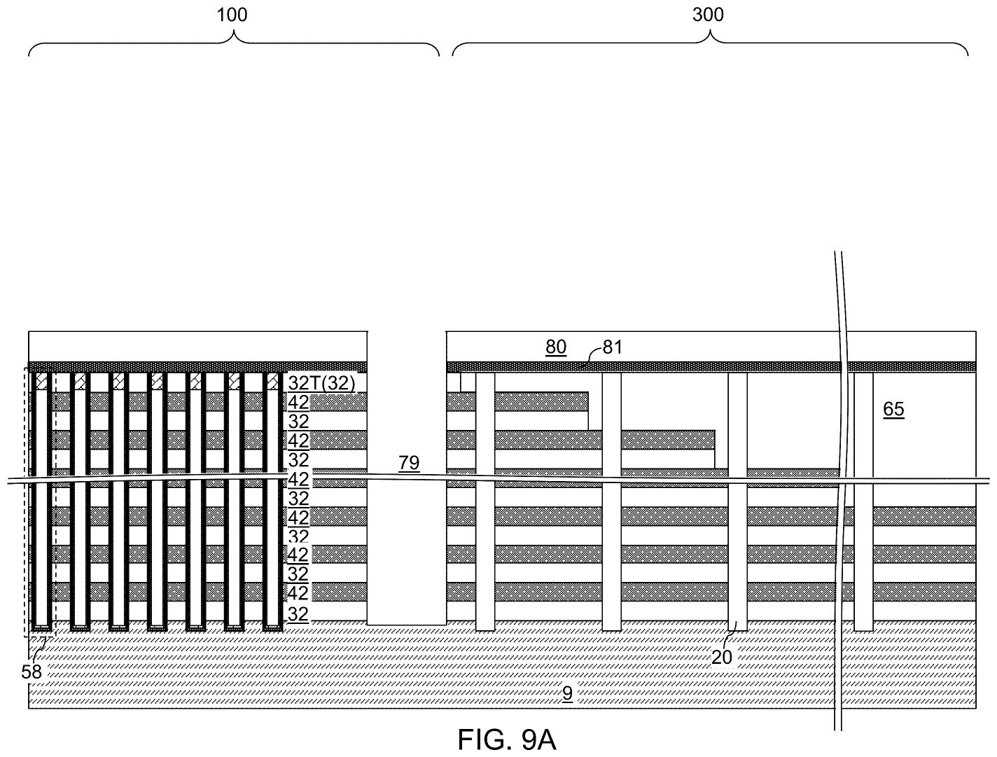

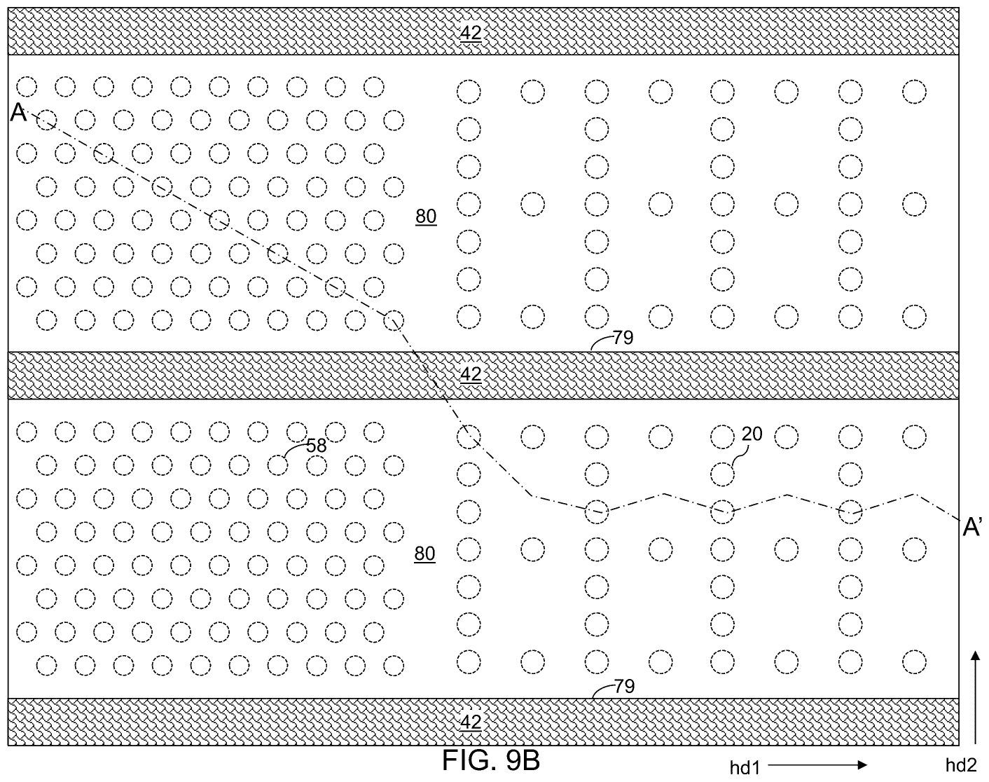

Referring to FIGS. 9A and 9B, a layer stack (81, 80) including an optional contact-level etch-stop dielectric layer 81 and a primary contact-level dielectric layer 80 can be formed over the alternating stack (32, 42), the memory opening fill structures 58, and the stepped dielectric material portion 65. The contact-level etch-stop dielectric layer 81 (if present) comprises an etch-stop dielectric material, i.e., a dielectric material that can function as an etch-strop structure. The contact-level etch-stop dielectric layer 81 can be used as an etch stop layer during a subsequent etch of the primary contact-level dielectric layer 80 to form drain contact via cavities extending to the drain regions 63. For example, the contact-level etch-stop dielectric layer 81 may comprise silicon carbonitride (SiCN). In one embodiment, the contact-level etch-stop dielectric layer 81 may consist essentially of silicon carbonitride. The contact-level etch-stop dielectric layer 81 may be formed by chemical vapor deposition. The thickness of the contact-level etch-stop dielectric layer 81 may be in a range from 5 nm to 60 nm, such as from 10 nm to 30 nm, although lesser and greater thicknesses may also be employed. The primary contact-level dielectric layer 80 comprises a dielectric material, such as undoped silicate glass (i.e., silicon oxide) or a doped silicate glass. The thickness of the primary contact-level dielectric layer 80 may be in a range from 100 nm to 600 nm, such as from 200 nm to 400 nm, although lesser and greater thicknesses may also be employed.

A photoresist layer (not shown) can be applied over the layer stack (81, 80), and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the layer stack (81, 80), the alternating stack (32, 42), and the stepped dielectric material portion 65, and to a top surface of the carrier substrate 9. Lateral isolation trenches 79 laterally extending along the first horizontal direction hd1 can be formed through the alternating stack (32, 42), the stepped dielectric material portion 65, and the layer stack (81, 80). Each of the lateral isolation trenches 79 may comprise a respective pair of lengthwise sidewalls that are parallel to the first horizontal direction hd1 and vertically extend from the top surface of the layer stack (81, 80) to the top surface of the carrier substrate 9. A surface of the carrier substrate 9 can be physically exposed underneath each lateral isolation trench 79. The photoresist layer can be subsequently removed, for example, by ashing.

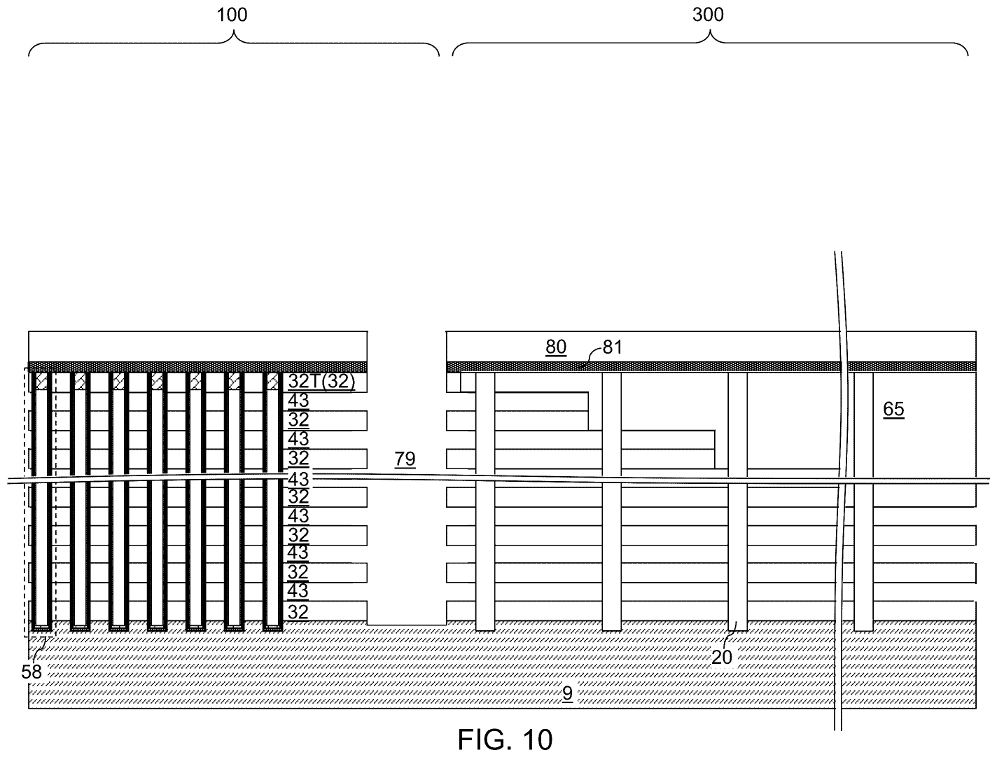

Referring to FIG. 10, an etchant that selectively etches the material of the sacrificial material layers 42 with respect to the material of the insulating layers 32, the contact-level etch-stop dielectric layer 81, and the primary contact-level dielectric layer 80 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the contact-level etch-stop dielectric layer 81, the primary contact-level dielectric layer 80, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

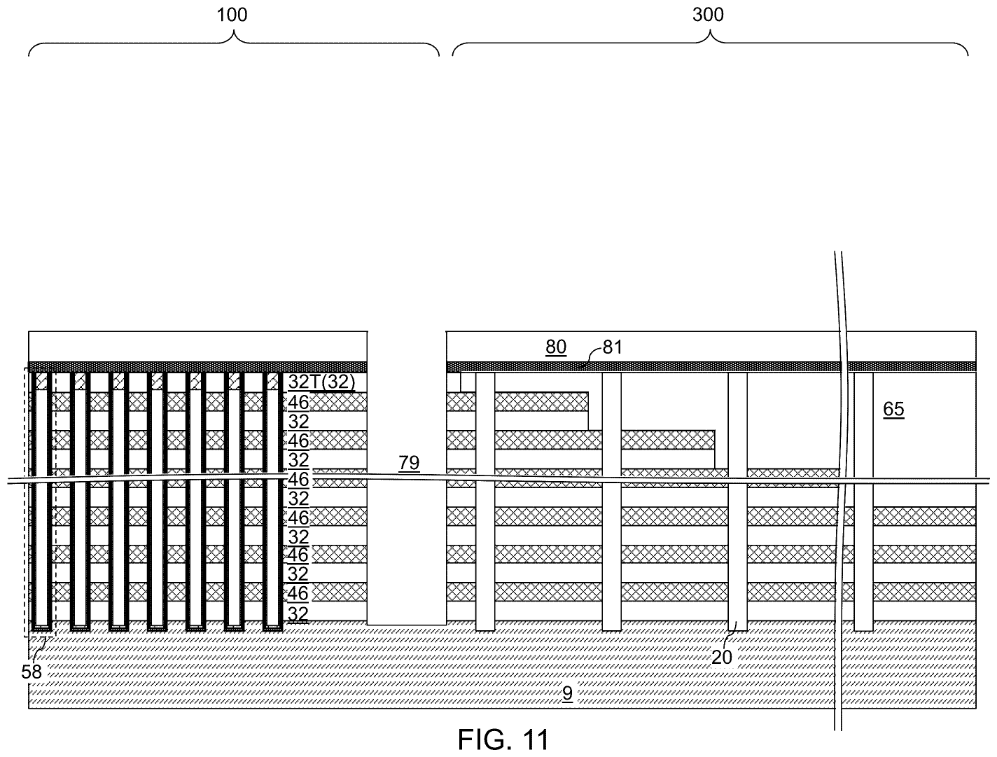

Referring to FIG. 11, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of each lateral isolation trench 79, and over the top surface of the layer stack (81, 80) to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the layer stack (81, 80). Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the layer stack (81, 80).

The deposited metallic material of the continuous electrically conductive material layer is etched back from the sidewalls of each lateral isolation trench 79 and from above the layer stack (81, 80) by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

Each electrically conductive layer 46 may be embedded within a respective outer blocking dielectric layer 44, which may comprise a dielectric metal oxide material, such as aluminum oxide. Each outer blocking dielectric layer 44 may have a pair of horizontally-extending portions in contact with a respective one of the insulating layers 32, and a plurality of tubular portions laterally surrounding a respective one of the memory opening fill structures 58 and connecting the pair of horizontally-extending portions. The thickness of each outer blocking dielectric layer 44 may be in a range from 1 nm to 6 nm, although lesser and greater thicknesses may also be employed.

Generally, an assembly of an alternating stack (32, 46) and memory opening fill structures 58 can be formed. The alternating stack (32, 46) comprises a vertically alternating sequence of insulating layers 32 and electrically conductive layers 46. The memory opening fill structures 58 vertically extend through the alternating stack (32, 46). Each of the memory opening fill structures 58 comprises a respective vertical stack of memory elements (which may comprises portions of a memory material layer 54 located at levels of the electrically conductive layers 46), a respective vertical semiconductor channel 60, and a respective drain region 63. At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

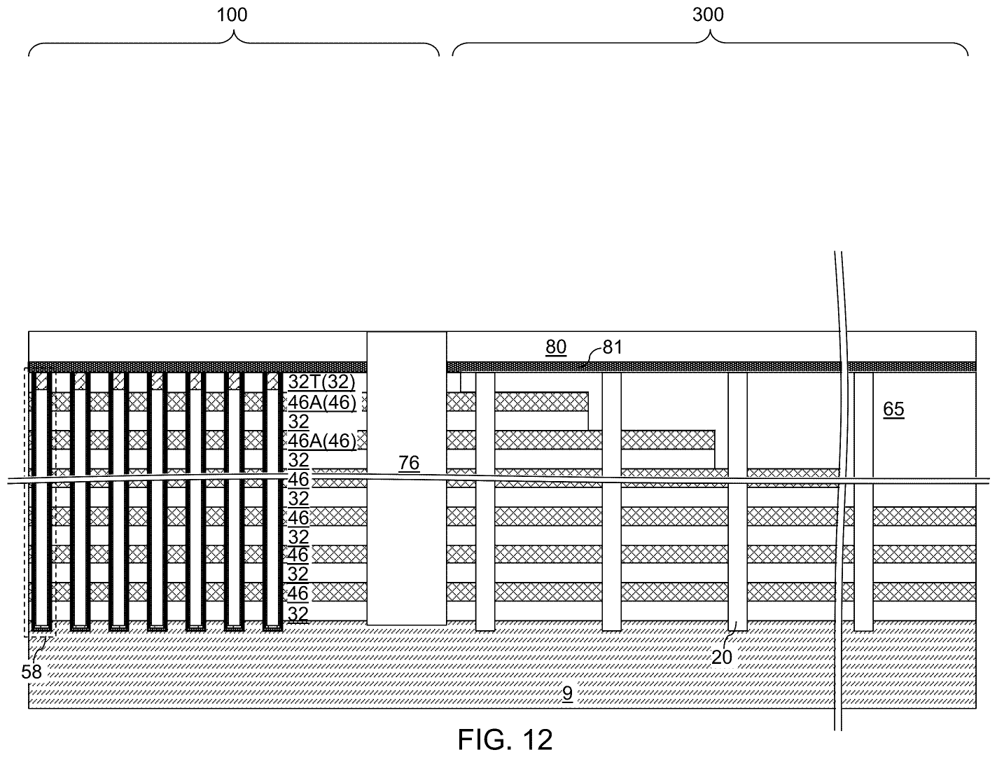

Referring to FIG. 12, a dielectric fill material, such as silicon oxide can be deposited in the lateral isolation trenches 79. Excess portions of the dielectric fill material can be removed from above the layer stack (81, 80). Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

An alternating stack (32, 46) of insulating layers 32 and electrically conductive layers 46 can be formed in a memory block area between each neighboring pair of lateral isolation trench fill structures 76. The alternating stack (32, 46) can include at least one drain-select-level electrically conductive layer 46A (i.e., at least one drain side select gate electrode) which is employed to activate or deactivate NAND strings (e.g., the memory opening fill structures 58 and adjacent portions of the electrically conductive layers 46) vertically extending through the alternating stack (32, 46). A subset of the electrically conductive layers 46 that underlies the drain-select-level electrically conductive layers 46A comprises word lines, which comprise control electrodes of the NAND strings. A subset of one or more bottommost electrically conductive layers 46 which underlies the word lines comprises source side select gate electrodes.

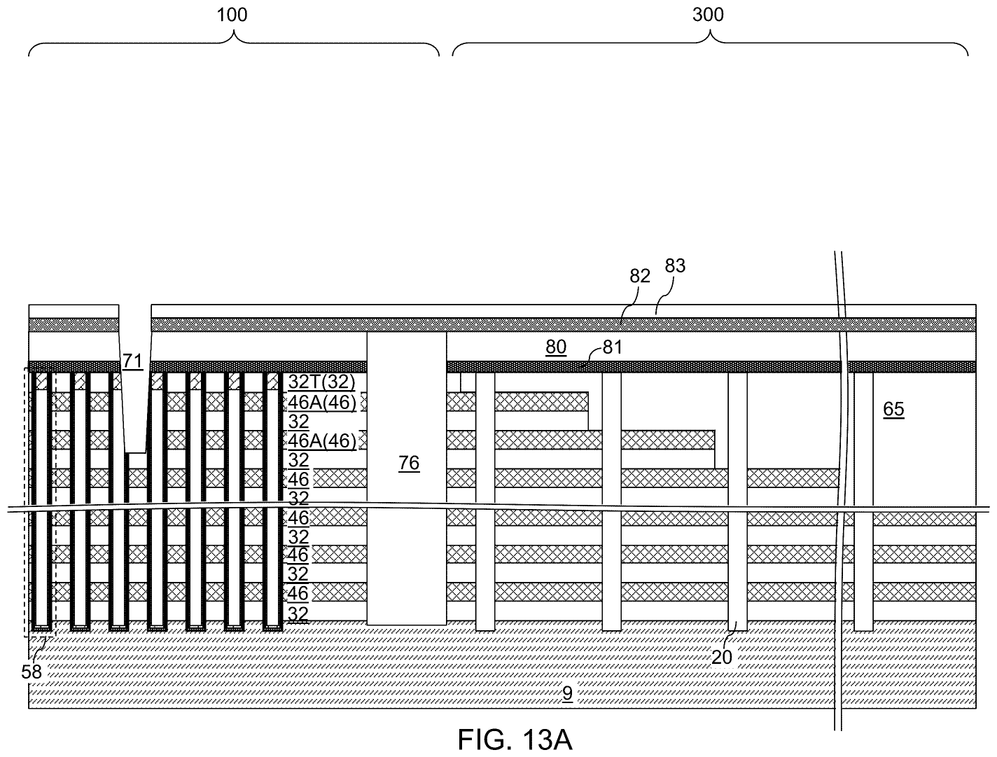

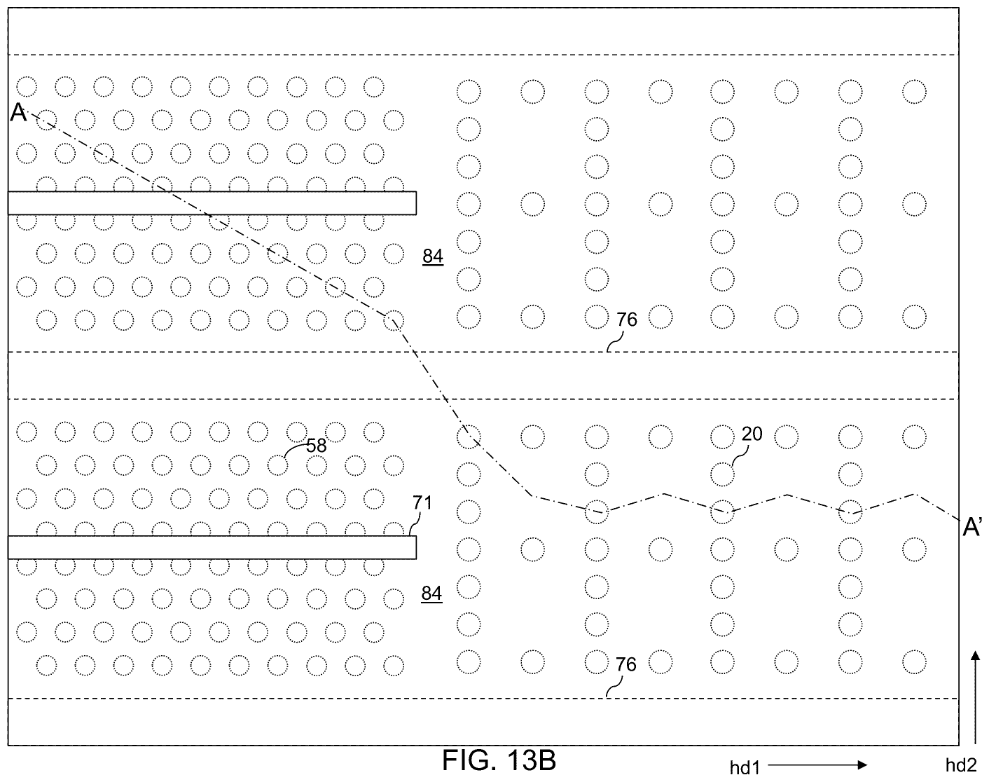

Referring to FIGS. 13A and 13B, a hardmask layer 82 and an optional pad layer 83 can be formed over the layer stack (81, 80). The hard mask layer 82 comprises a hard mask material, such as silicon nitride or titanium nitride, and may have a thickness in a range from 10 nm to 80 nm, such as from 20 nm to 60 nm, although lesser and greater thicknesses may also be employed. The optional pad layer 83, if present, may comprise a dielectric pad material, such as silicon oxide, and may have a thickness in a range from 5 nm to 80 nm, such as from 10 nm to 60 nm, although lesser and greater thicknesses may also be employed.

A photoresist layer (not shown) can be applied over the hardmask layer 82 and the optional pad layer 83, and can be lithographically patterned to form line-shaped openings laterally extending along the first horizontal direction hd1 in the memory array region 100. The line-shaped openings may have horizontal cross-sectional shapes of an elongated rectangle that laterally extends between a respective neighboring pair of rows of memory opening fill structures 58, i.e., between a first row of memory opening fill structures 58 and a second row of memory opening fill structures 58.

An anisotropic etch process can be performed to transfer the pattern of the openings in the photoresist layer through the optional pad layer 83, the hardmask layer 82, the layer stack (81, 80), through the topmost insulating layer 32T, and through each of the drain-select-level electrically conductive layers 46A. Lateral isolation cavities 71 having horizontal cross-sectional shapes of elongated rectangles can be formed through the optional pad layer 83, the hardmask layer 82, the layer stack (81, 80), through the topmost insulating layer 32T, and through each of the drain-select-level electrically conductive layers 46A. Thus, each drain-select-level electrically conductive layer 46A may be divided into a respective plurality of drain-select-level electrically conductive layers (i.e., drain side select gate electrodes) 46A that are laterally spaced apart from each other along the second horizontal direction hd2 (which may be a bit line direction) by at least one lateral isolation cavity 71.

Each lateral isolation cavity 71 may comprise a pair of lengthwise sidewalls having a straight vertical cross-sectional profile, i.e., having a respective straight surface segment in a vertical cross-sectional profile. Each straight surface segment of the lengthwise sidewalls of the lateral isolation cavities 71 may vertically extend from the topmost surface of the optional pad layer 83 and the hardmask layer 82 to a bottom surface of a respective one of the lateral isolation cavities 71. In one embodiment, the memory opening fill structures 58 are arranged in rows that laterally extend generally along a first horizontal direction hd1, and sidewalls of two rows of memory opening fill structures 58 may be physically exposed underneath each lateral isolation cavity 71. Generally, each lateral isolation cavity 71 vertically extends through the layer stack (81, 80) and a subset 46A of the electrically conductive layers 46.

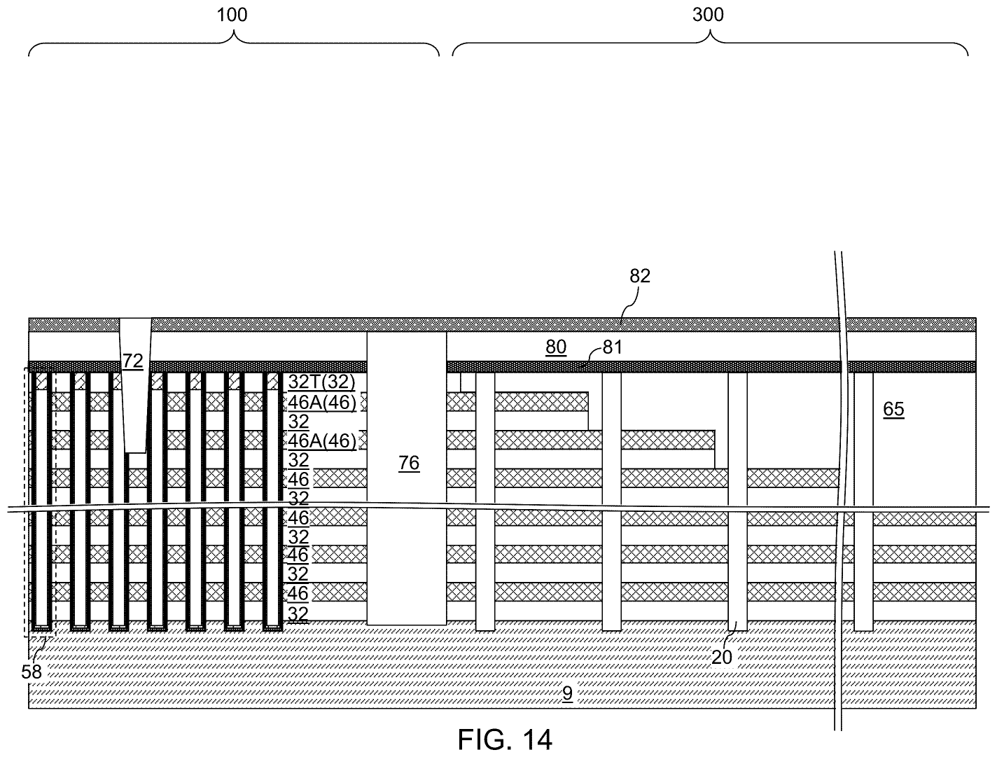

Referring to FIG. 14, a dielectric fill material, such as undoped silicate glass or a doped silicate glass may be conformally deposited in the lateral isolation cavities 71 and over the optional pad layer 83 and the hardmask layer 82. A planarization process, such as a chemical mechanical polishing process, can be performed to remove the optional pad layer 83 (if present) and portions of the dielectric fill material that overlie the horizontal plane including the top surface of the hardmask layer 82. Each remaining portion of the dielectric fill material that fills a respective lateral isolation cavity 71 constitutes a lateral isolation structure 72. The top surfaces of the lateral isolation structures 72 may be formed within the horizontal plane including the top surface of the hardmask layer 82.

In summary, each lateral isolation structure 72 may be formed through the layer stack (81, 80) and a subset of the electrically conductive layers 46. In one embodiment, the memory opening fill structures 58 are arranged in rows that laterally extend generally along a first horizontal direction hd1. Each lateral isolation structure 72 may be in contact with sidewalls of a respective set of two rows of memory opening fill structures 58.

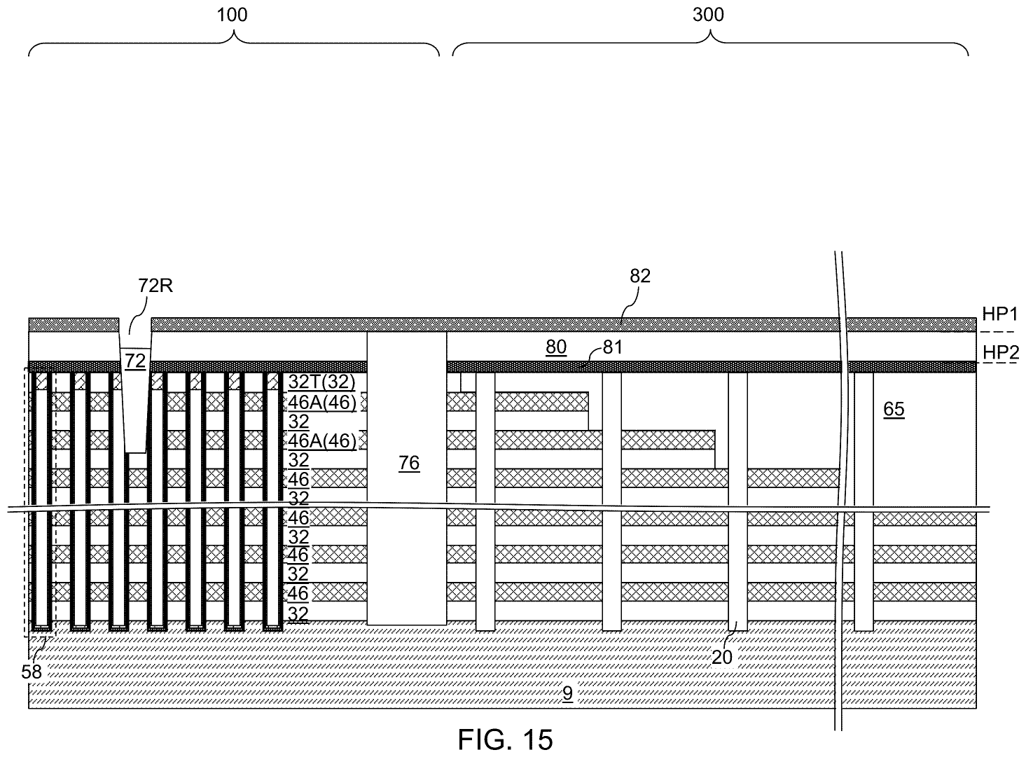

Referring to FIG. 15, a recess etch process can be performed to vertically recess the top surface of each lateral isolation structure 72 below a first horizontal plane HP1 including the top surface of the topmost surface of the layer stack (81, 80) such as the top surface of the primary contact-level dielectric layer 80. A recess 72R is formed over the lateral isolation structure 72. For example, an anisotropic etch process can be performed to etch the material of the lateral isolation structures 72 selective to the material of the hardmask layer 82. The top surfaces of the lateral isolation structures 72 (which correspond to the bottom surfaces of the recesses 72R) may be formed between the first horizontal plane HP1 and a second horizontal plane HP2 including the bottom surface of the primary contact-level dielectric layer 80. The vertical distance between the top surfaces of the lateral isolation structures 72 and the first horizontal plane HP1 may be in a range from 10% to 80%, such as from 20% to 30%, of the thickness of the primary contact-level dielectric layer 80.

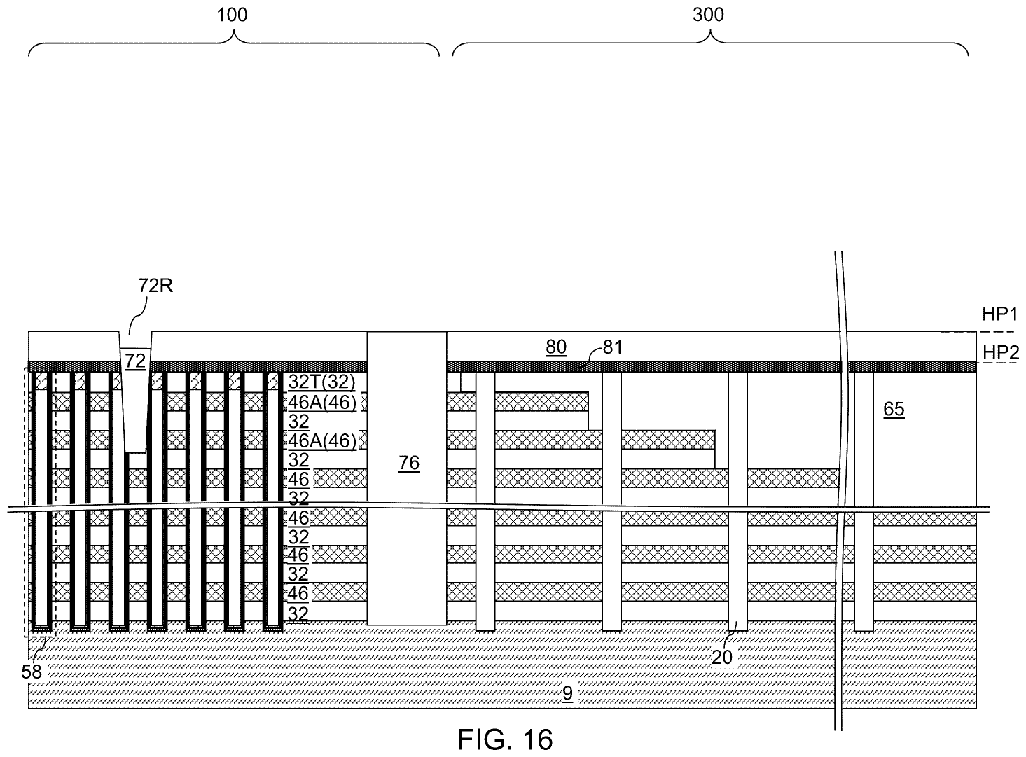

Referring to FIG. 16, an optional selective etch process can be performed to remove the hardmask layer 82 selective to the materials of the primary contact-level dielectric layer 80 and the lateral isolation structures 72. For example, a wet etch process may be performed to remove the hardmask layer 82 selective to the materials of the primary contact-level dielectric layer 80 and the lateral isolation structures 72. Alternatively, the hardmask layer 82 may be retained in the final memory device.

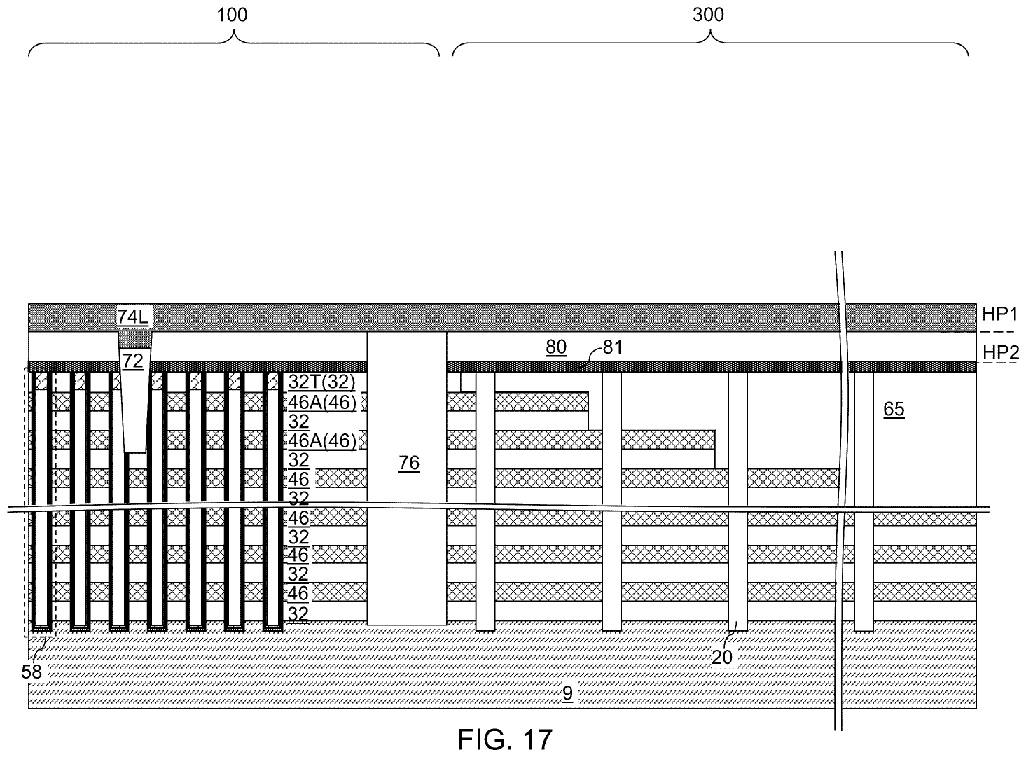

Referring to FIG. 17, an etch-stop cap material may be conformally deposited in the recesses 72R overlying the lateral isolation structures 72 and over the layer stack (81, 80) to form an etch-stop cap material layer 74L. The etch-stop cap material layer 74L may comprise a dielectric etch-stop material that is the same as or different from the material of the contact-level etch-stop dielectric layer 81. For example, the contact-level etch-stop dielectric layer 81 may comprise silicon carbonitride, and the etch-stop cap material layer 74L may comprise silicon nitride, aluminum oxide or silicon carbonitride. In one embodiment, the thickness of the etch-stop cap material layer 74L may be greater than one half of the width of each recess 72R. Thus, the entire volume of each recess 72R over the lateral isolation structures 72 can be filled with the etch-stop cap material layer 74L.

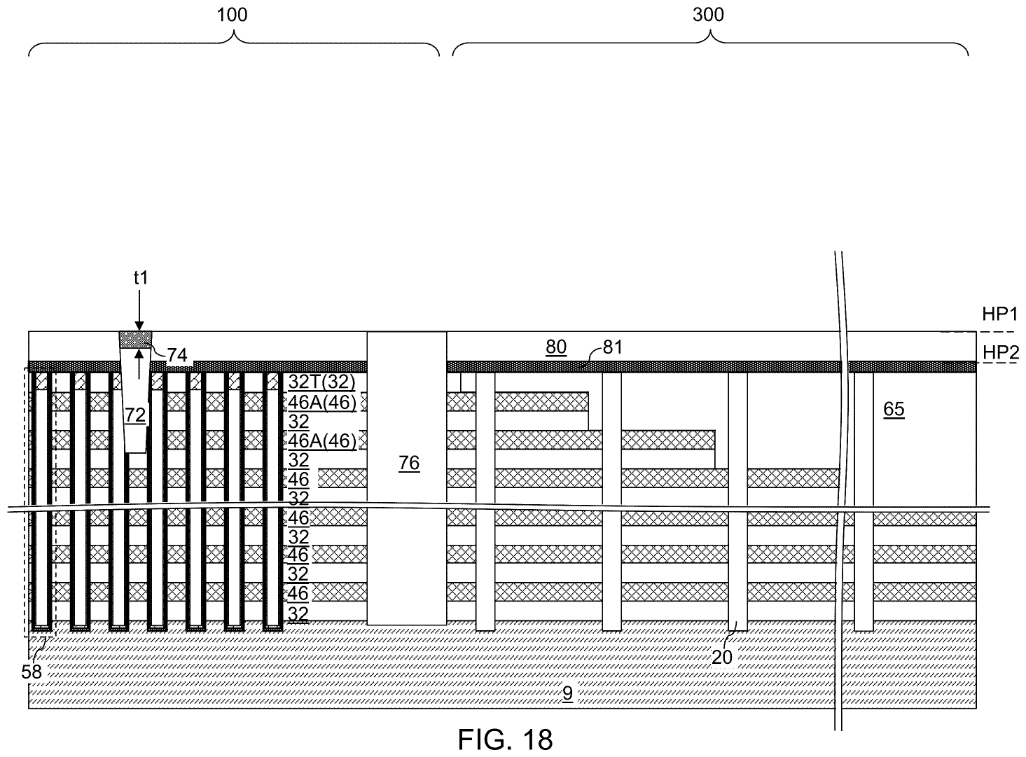

Referring to FIG. 18, portions of the etch-stop cap material layer 74L overlying the first horizontal plane HP1 may be removed by performing a planarization process, which may comprise a recess etch process or a chemical mechanical polishing process. For example, a recess etch process may be performed to remove the material of the etch-stop cap material layer 74L from above the first horizontal plane HP1. The recess etch process may comprise a wet etch process or a reactive ion etch process. The recess etch process may be selective to the material of the primary contact-level dielectric layer 80. Each remaining portion of the etch-stop cap material layer 74L that fills a respective recess 72R comprises an etch-stop isolation cap 74.

In summary, each etch-stop isolation cap 74 can be formed over a respective lateral isolation structure 72. In one embodiment, an entirety of a bottom periphery of an etch-stop isolation cap 74 may coincide with an entirety of a top periphery of an underlying lateral isolation structure 72. In one embodiment, the top surface of an etch-stop isolation cap 74 may be formed within the first horizontal plane HP1 that includes the top surface of the primary contact-level dielectric layer 80. Each lateral isolation structure 72 vertically extends through a first subset 46A of the electrically conductive layers 46 within the alternating stack (32, 46) and the layer stack (81, 80). In one embodiment, the bottom periphery of the etch-stop isolation cap 74 is located below a first horizontal plane HP1 including a top surface of the primary contact-level dielectric layer 80 and above a second horizontal plane HP2 including a bottom surface of the primary contact-level dielectric layer 80. Each etch-stop isolation cap 74 may have a first thickness t1, which may be in a range from 20 nm to 150 nm, such as from 30 nm to 100 nm, although lesser and greater thicknesses may also be employed.

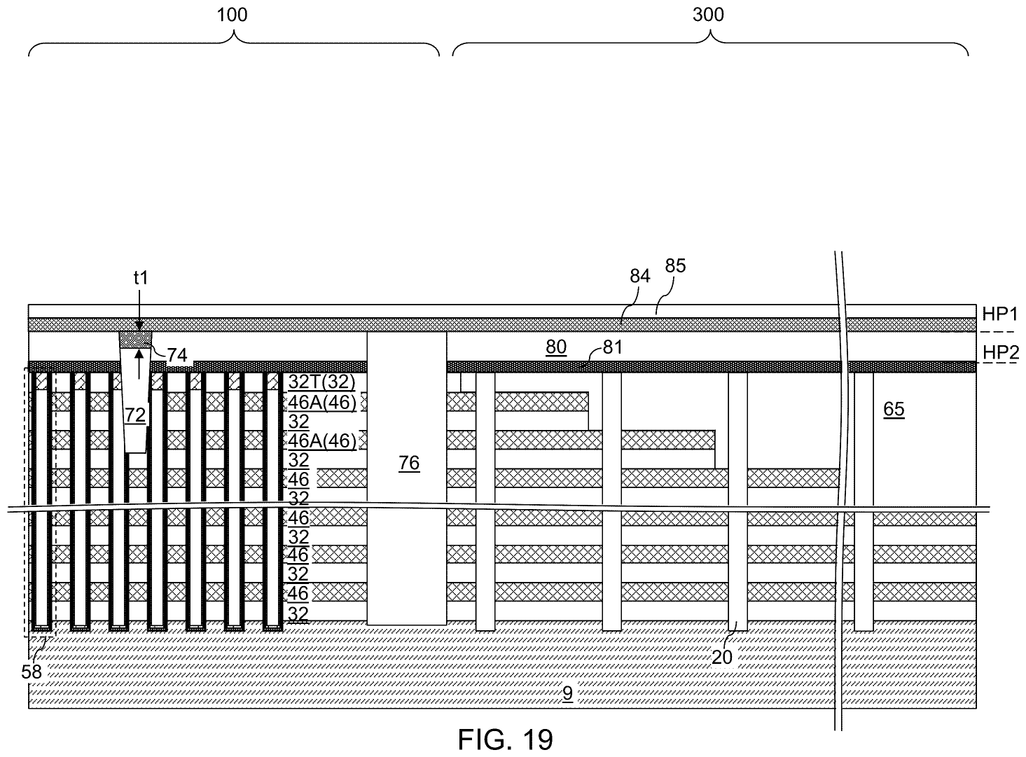

Referring to FIG. 19, at least one contact-level dielectric capping layer (84, 85) can be deposited over the layer stack (81, 80). The at least one contact-level dielectric capping layer 84 may comprise a first contact-level dielectric capping layer 84 comprising a first dielectric capping material, such as silicon nitride, and a second contact-level dielectric capping layer 85 comprising a second dielectric capping material, such as silicon oxide. The thickness of the first contact-level dielectric capping layer 84 may be in a range from 20 nm to 100 nm, although lesser and greater thicknesses may also be employed. The thickness of the second contact-level dielectric capping layer 85 may be in a range from 20 nm to 100 nm, although lesser and greater thicknesses may also be employed.

The combination of the layer stack (81, 80) of the optional contact-level etch-stop dielectric layer 81 and the primary contact-level dielectric layer 80 and the at least one contact-level dielectric capping layer (84, 85) constitutes contact-level dielectric layers (81, 80, 84, 85). In one embodiment, the thickness of the primary contact-level dielectric layer 80 may be at least 50% of the total thickness of the contact-level dielectric layers (81, 80, 84, 85). In one embodiment, each etch-stop isolation cap 74 may have a top surface that contacts a bottom surface of the at least one contact-level dielectric capping layer (84, 85).

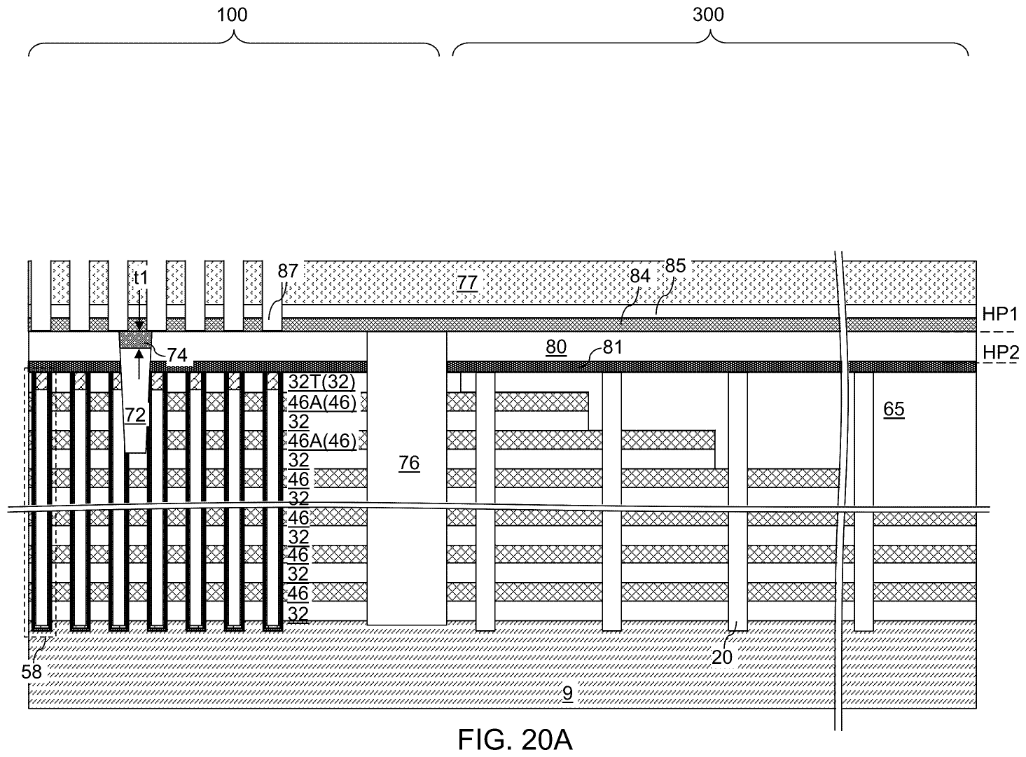

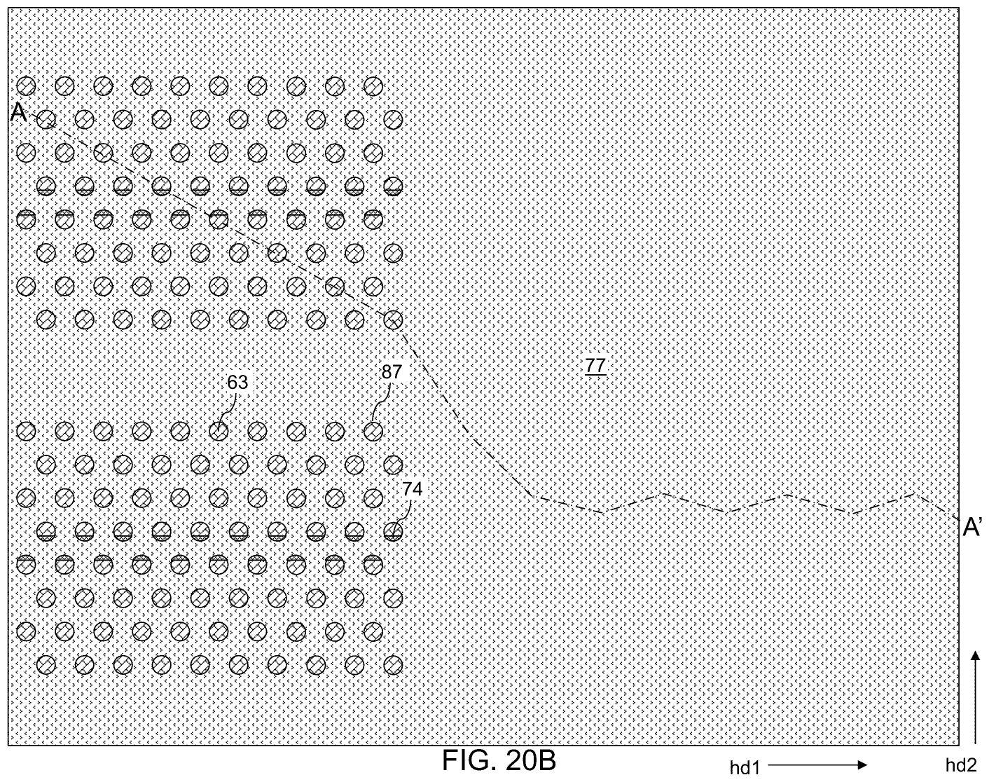

Referring to FIGS. 20A and 20B, a first photoresist layer 77 may be applied over the at least one contact-level dielectric capping layer (84, 85), and can be lithographically patterned with discrete openings having the same pattern as the pattern of the memory opening fill structures 58. Ideally, each of the discrete openings in the first photoresist layer 77 is formed entirely within the area of the memory opening fill structures 58. However, overlay variations between the pattern of the discrete openings in the first photoresist layer 77 and the pattern of the memory opening fill structures 58 may be introduced during the lithographic patterning of the discrete openings in the first photoresist layer 77.

An anisotropic etch process can be subsequently performed to transfer the pattern of the openings in the first photoresist layer 77 through the contact-level dielectric layers (81, 80, 84, 85). The anisotropic etch process may comprise a first step that etches unmasked portions of the at least one contact-level dielectric capping layer (84, 85). For example, the first step of the anisotropic etch process may comprise a sequence of a first anisotropic etch phase that etches the material of the second contact-level dielectric capping layer 85 selective to the material of the first contact-level dielectric capping layer 84, and a second anisotropic etch phase that etches the material of the first contact-level dielectric capping layer 84 while stopping on the etch-stop isolation caps 74, which are used as etch stops to prevent or reduce over etching. In one embodiment shown in FIG. 20B, an etch-stop isolation cap 74 may comprise two rows of physically exposed top surface segments after the first step of the anisotropic etch process. Each physically exposed top surface segment may have a planar shape including an arc segment and a chord segment that is parallel to the first horizontal direction hd1. Drain contact via cavities 87 are formed in volumes from which the materials of the at least one contact-level dielectric capping layer (84, 85) are removed.

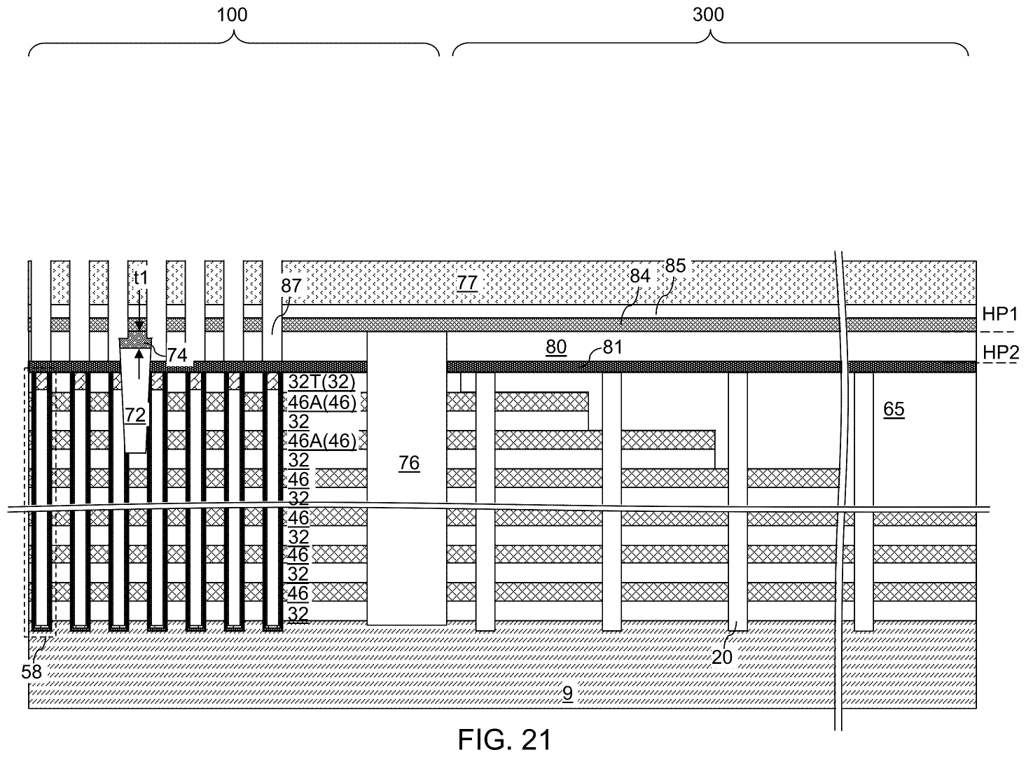

Referring to FIG. 21, a second step of the anisotropic etch process can be performed to etch unmasked portions of the primary contact-level dielectric layer 80 selective to the material of the etch-stop isolation caps 74. In one embodiment, the etch chemistry of the second step of the anisotropic etch process may be selective to the material of the contact-level etch-stop dielectric layer 81, if present. Thus, the drain contact via cavities 87 can be vertically extended through the primary contact-level dielectric layer 80 using the contact-level etch-stop dielectric layer 81 as an etch stop. The pattern of the etched portions of the primary contact-level dielectric layer 80 may be the composite pattern of the intersection of the pattern of the openings in the first photoresist layer 77 and the pattern of the primary contact-level dielectric layer 80. Thus, the combination of the first photoresist layer 77 and the etch-stop isolation caps 74 can be employed as etch mask structures during the second step of the anisotropic etch process. Unmasked top surface segments of the etch-stop isolation caps 74 may be collaterally vertically recessed during the second step of the anisotropic etch process.

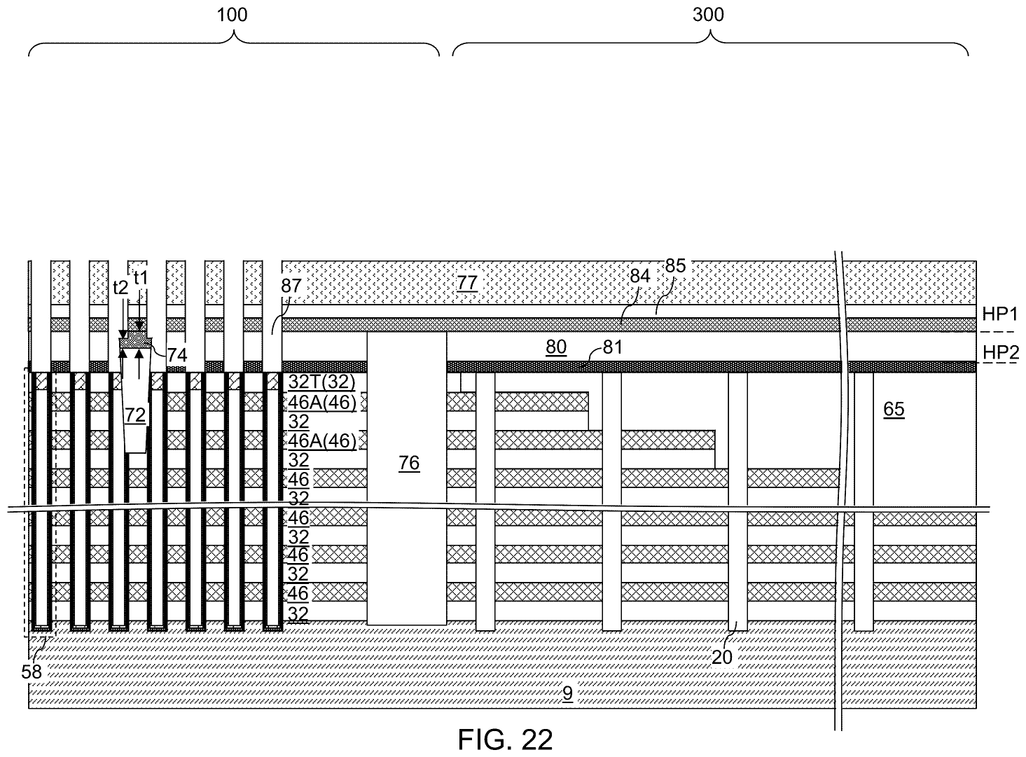

Referring to FIG. 22, if the contact-level etch-stop dielectric layer 81 is present, a third step of the anisotropic etch process can be performed to etch unmasked portions of the contact-level etch-stop dielectric layer 81 selective to the material of the drain regions 63. In some embodiments, unmasked portions of the etch-stop isolation caps 74 may be collaterally vertically recessed during the third step of the anisotropic etch process. Generally, the various steps of the anisotropic etch process forms drain contact via cavities 87 such that top surfaces of the drain regions 63 are exposed underneath the drain contact via cavities 87 employing etch chemistries that are selective to the material of the etch-stop isolation caps 74. Portions of the etch-stop isolation caps 74 that are exposed within the areas of the openings in the first photoresist layer 77 can be thinned to a second thickness t2, which is less than the first thickness t1. The second thickness t2 may be in a range from 10% to 95%, such as from 40% to 90%, and/or from 60% to 85%, of the first thickness t1, although lesser and greater ranges may also be employed. The first photoresist layer 77 can be subsequently removed, for example, by ashing.

In summary, the drain contact via cavities 87 are formed through at least the layer stack (81, 80) by performing an etch process that etches materials of the layer stack (81, 80) selective to the etch-stop isolation caps 74. Top surfaces of the drain regions 63 are exposed underneath the drain contact via cavities 87. Thus, the combination of the etch-stop isolation caps 74 and the contact-level etch-stop dielectric layer 81 may be used to reduce the impact of the overlay variations between the drain contact via cavities 87 and drain regions 63, and to prevent or reduce extension of the drain contact via cavities 87 to the drain side select gate electrodes 46A. Specifically, vertical protrusion of the drain contact via cavities 87 into the lateral isolation structures 72 is prevented or reduced due to the presence of the etch-stop isolation caps 74. This reduced or prevents short circuits between the drain contact via structures to be formed in the drain contact via cavities 87 and the drain side select gate electrodes 46A.

In one embodiment, each etch-stop isolation cap 74 has a first thickness t1 in a continuous area that does not have any areal overlap with the openings in the first photoresist layer 77 in a plan view, and has a second thickness t2 in discrete areas having an areal overlap with a respective one of the openings in the first photoresist layer 77 in the plan view. The second thickness t2 is less than the first thickness t1.

In one embodiment, each drain contact via cavity 87 that is laterally bounded by a lateral isolation structure 72 (i.e., having a sidewall that is a surface of the lateral isolation structure 72) may have a respective vertical cross-sectional profile having a respective stepped sidewall. In one embodiment, each stepped sidewall of the vertical cross-sectional profiles has an upper vertically-extending surface segment, a lower vertically-extending surface segment, and a horizontal connecting surface segment that connects the upper vertically-extending surface segment and the lower vertically-extending surface segment. In one embodiment, for each stepped sidewall of the vertical cross-sectional profiles, the upper vertically-extending surface segment comprises a sidewall surface segment of the at least one contact-level dielectric capping layer (84, 85) and a first sidewall segment of etch-stop isolation cap 74. The lower vertically-extending surface segment comprises a second sidewall segment of the etch-stop isolation cap 74, and optionally, a sidewall segment of lateral isolation structure 72. The connecting surface segment comprises a horizontal surface segment of a portion of the etch-stop isolation cap 74 that has the thickness t2.

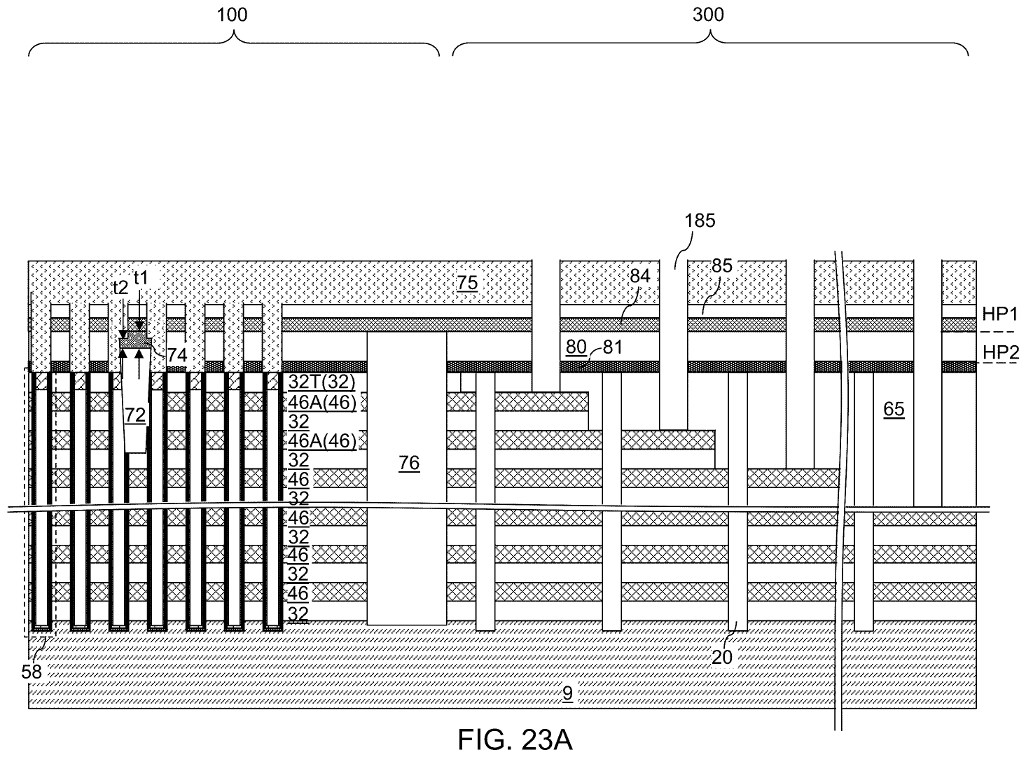

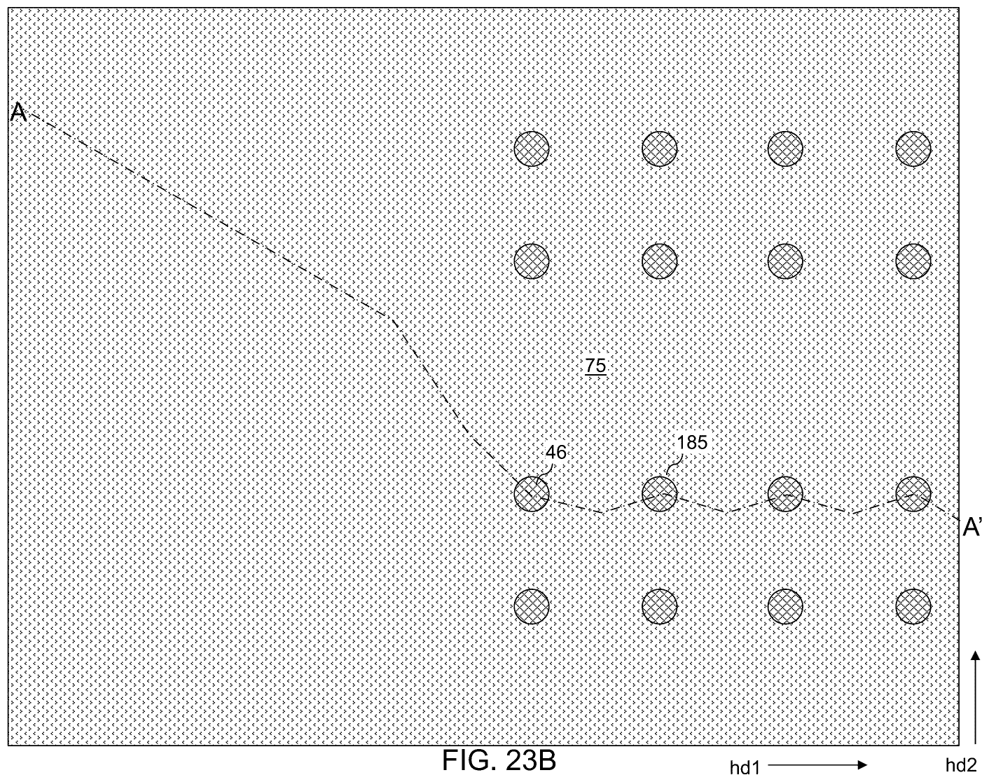

Referring to FIGS. 23A and 23B, a second photoresist layer 75 can be applied over the at least one contact-level dielectric capping layer (84, 85), and can be lithographically patterned to form openings in areas in the contact region 300 that overlies a respective horizontally-extending surface segment of the electrically conductive layers 46. An anisotropic etch process can be performed to transfer the pattern of the openings in the second photoresist layer 75 through the at least one contact-level dielectric capping layer (84, 85), the primary contact-level dielectric layer 80, the contact-level etch-stop dielectric layer 81, and the stepped dielectric material portion 65. Layer contact via cavities 185 can be formed through the at least one contact-level dielectric capping layer (84, 85), the primary contact-level dielectric layer 80, the contact-level etch-stop dielectric layer 81, and the stepped dielectric material portion 65 on a top surface of a respective one of the electrically conductive layers 46. Each electrically conductive layer 46 may have a top surface segment that is exposed to a respective overlying layer contact via cavity 185. The second photoresist layer 75 can be subsequently removed, for example, by ashing. In an alternative embodiment, the drain contact via cavities 87 and the layer contact via cavities 185 may be formed during the same photolithography and etching steps using the same photoresist layer.

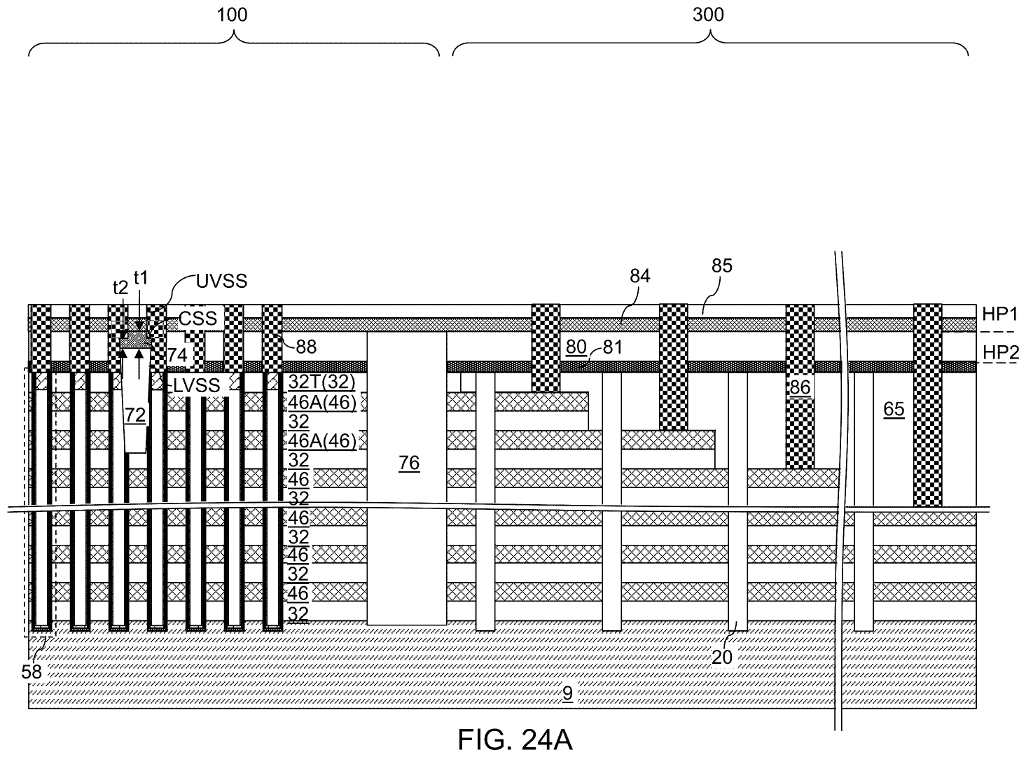

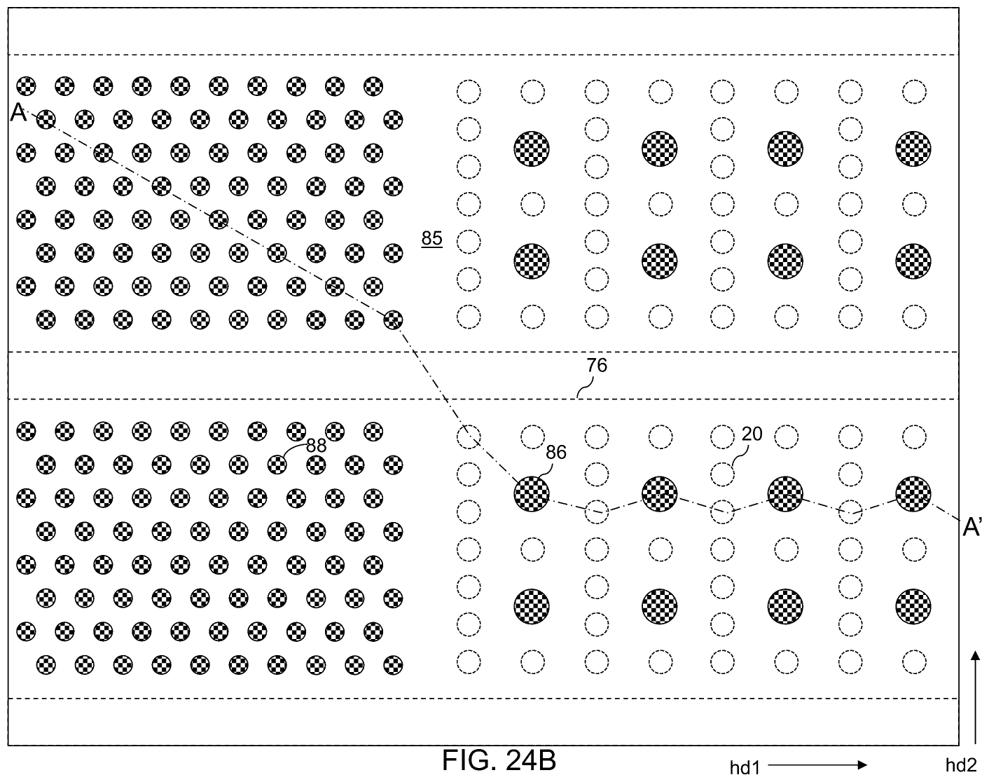

Referring to FIGS. 24A and 24B, at least one metallic material can be deposited in the drain contact via cavities 87 and the layer contact via cavities 185. The at least one metallic material may comprise a metallic barrier material (such as TiN, TaN, WN, and/or MoN) and a metal fill material (such as W, Ru, Co, Mo, Cu, etc.). Excess portions of the at least one metallic material can be removed from above the horizontal plane including the topmost surface of the at least one contact-level dielectric capping layer (84, 85). Each remaining portion of the at least one metallic material that fills a drain contact via cavity 87 comprises drain contact via structure 88. Each remaining portion of the at least one metallic material that fills a layer contact via cavity 185 comprises a layer contact via structure 86.

Each of the drain contact via structures 88 vertically extends through the contact-level dielectric layers (81, 80, 84, 85) and contacts a top surface of a respective drain region 63. A first subset of the drain contact via structures 88 has a respective vertical cross-sectional profile having a respective stepped sidewall that contacts a respective lateral isolation structure 72. Each stepped sidewall of the vertical cross-sectional profiles has an upper vertically-extending surface segment UVSS, a lower vertically-extending surface segment LVSS, and a horizontal connecting surface segment CSS that connects the upper vertically-extending surface segment UVSS and the lower vertically-extending surface segment LVSS.

In one embodiment, for each stepped sidewall of the vertical cross-sectional profiles, the upper vertically-extending surface segment UVSS contacts a sidewall surface segment of the at least one contact-level dielectric capping layer (84, 85) and a first sidewall segment of etch-stop isolation cap 74. The lower vertically-extending surface segment LVSS contacts a second sidewall segment of the etch-stop isolation cap 74 and optionally contacts a sidewall segment of lateral isolation structure 72. The connecting surface segment CSS contacts a horizontal surface segment of a portion of the etch-stop isolation cap 74 having the thickness t2.

All sidewalls of a second subset of the drain contact via structures 88 may be straight, and may vertically extend from a topmost surface of the contact-level dielectric layers (81, 80, 84, 85) to a bottommost surface of the contact-level dielectric layers (81, 80, 84, 85). The second subset of the drain contact via structures 88 is not in contact with any of the lateral isolation structures 72.

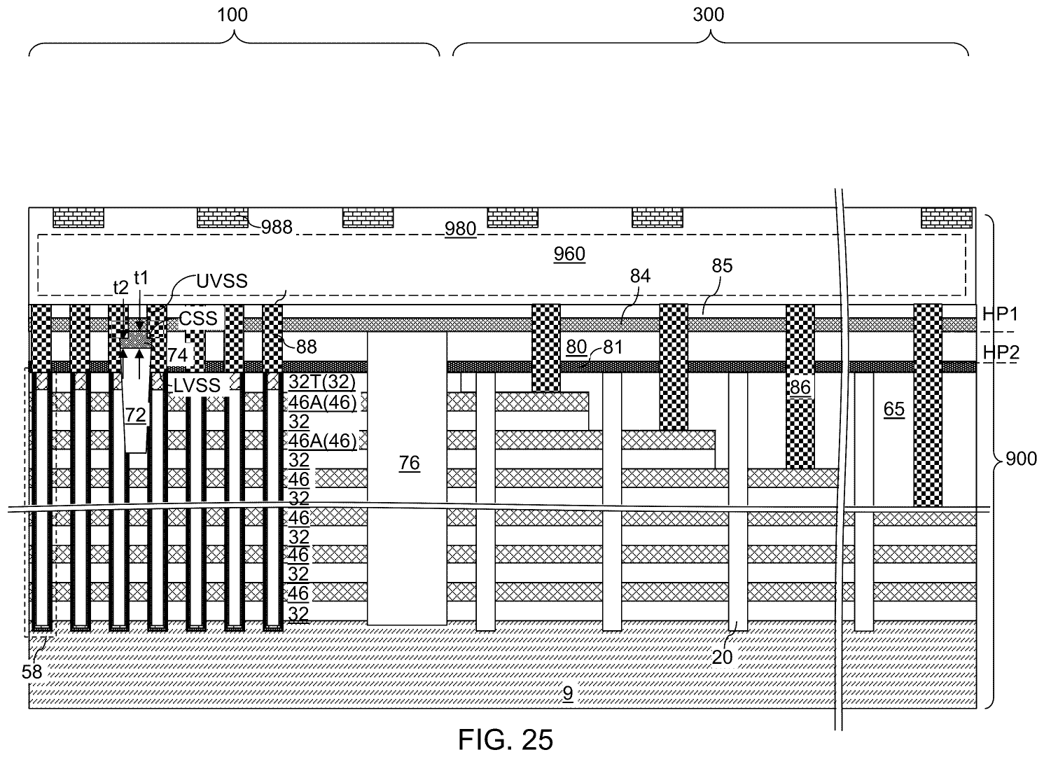

Referring to FIG. 25, additional dielectric material layers and additional metal interconnect structures can be formed over the layer stack (81, 80). The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the layer stack (81, 80) are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

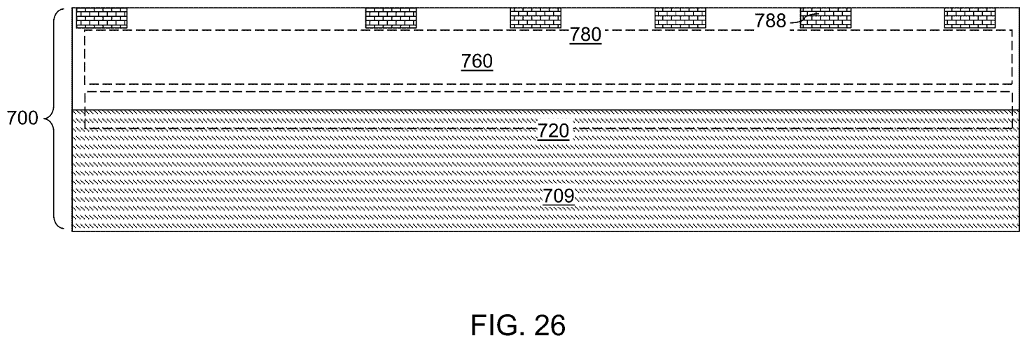

Referring to FIG. 26, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

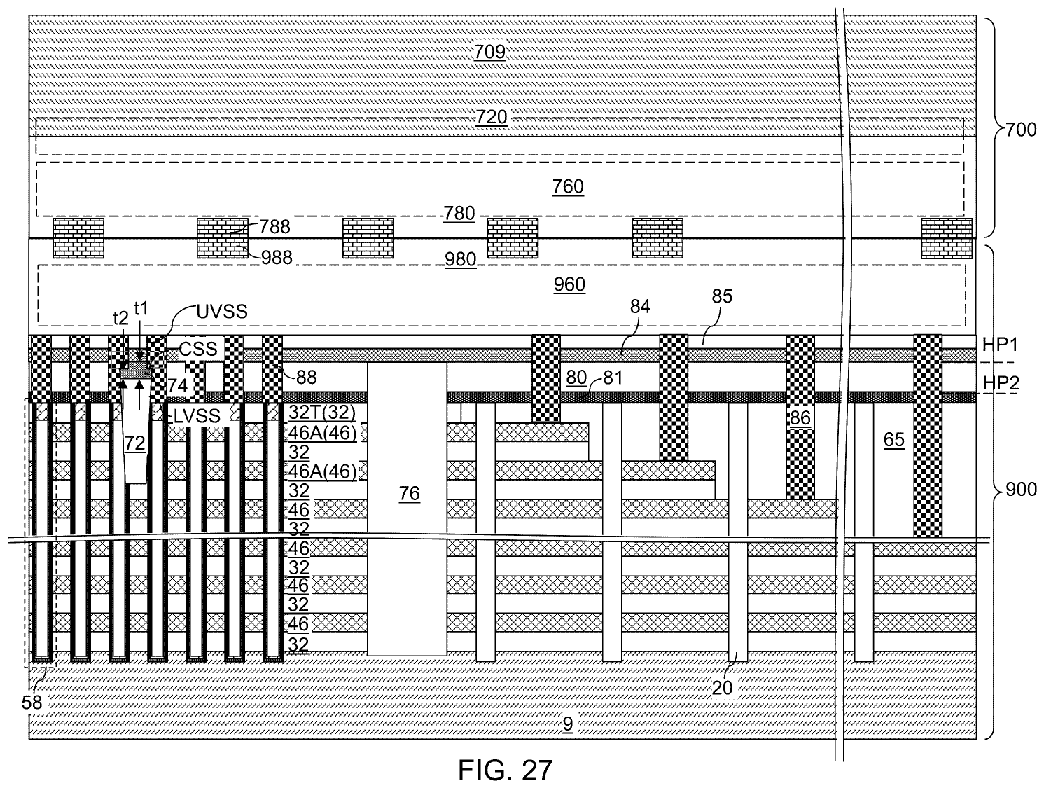

Referring to FIG. 27, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

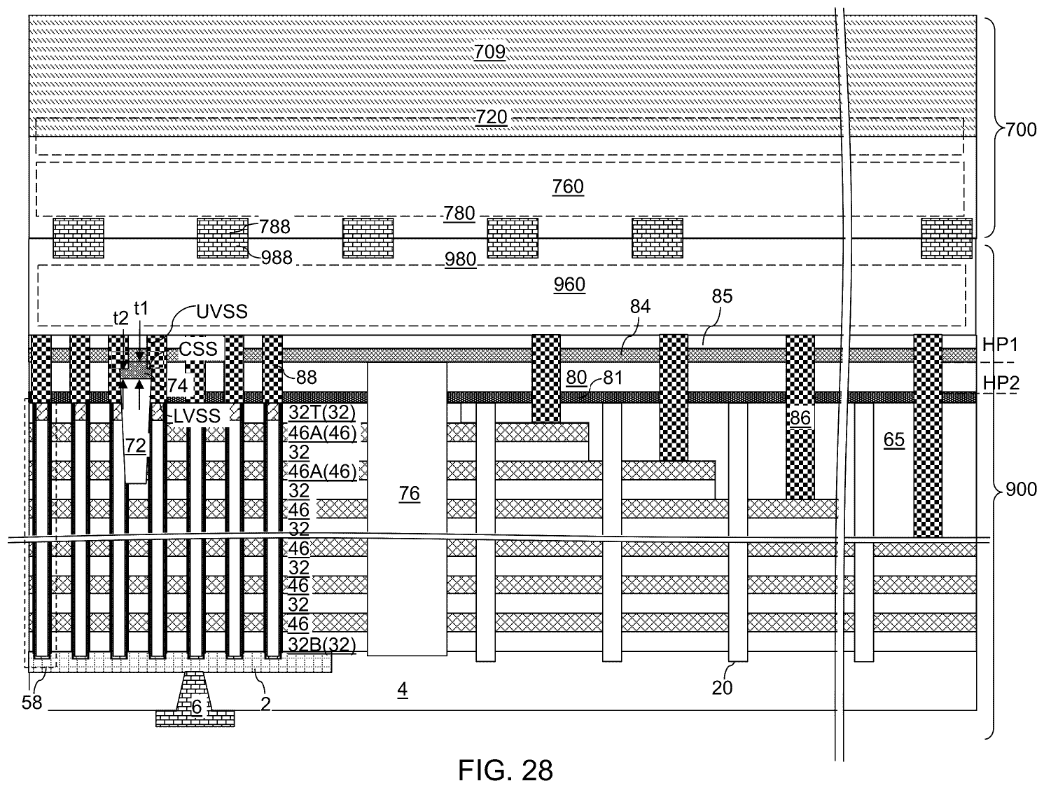

Referring to FIG. 28, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9.

A sequence of wet etch steps can be performed to sequentially remove portions of the memory film 50 that are exposed on the backside of the alternating stack (32, 46). For example, the inner blocking dielectric layer 52, the memory material layer 54, and the optional dielectric liner 56 (which may be, for example, a tunneling dielectric layer) of each memory film 50 can be removed from a region that is more distal from the bonding interface between the memory die 900 and the logic die 700 than a physically exposed planar surface of the bottommost insulating layer 32B is from the bonding interface. For the purpose of convenience, geometrical features of the exemplary structure and other exemplary structures in the present disclosure may be described in an orientation in which the logic die 700 overlies the memory die 900. Viewed in this orientation, the blocking dielectric layer 52, the memory material layer 54, and the optional dielectric liner 56 (which may be, for example, a tunneling dielectric layer) of each memory film 50 can be removed from below the horizontal plane including the bottom surface of the bottommost insulating layer 32B.

A heavily doped semiconductor (e.g., polysilicon) and/or a metallic (e.g. TiN/W bilayer) source layer 2 is formed in contact with exposed end portions of the vertical semiconductor channels 60. A backside dielectric 4 is formed over the source layer 2, and patterned to from at least one opening exposing the source layer 2. A backside contact structure 6 is formed in the opening in contact with the source layer 2.

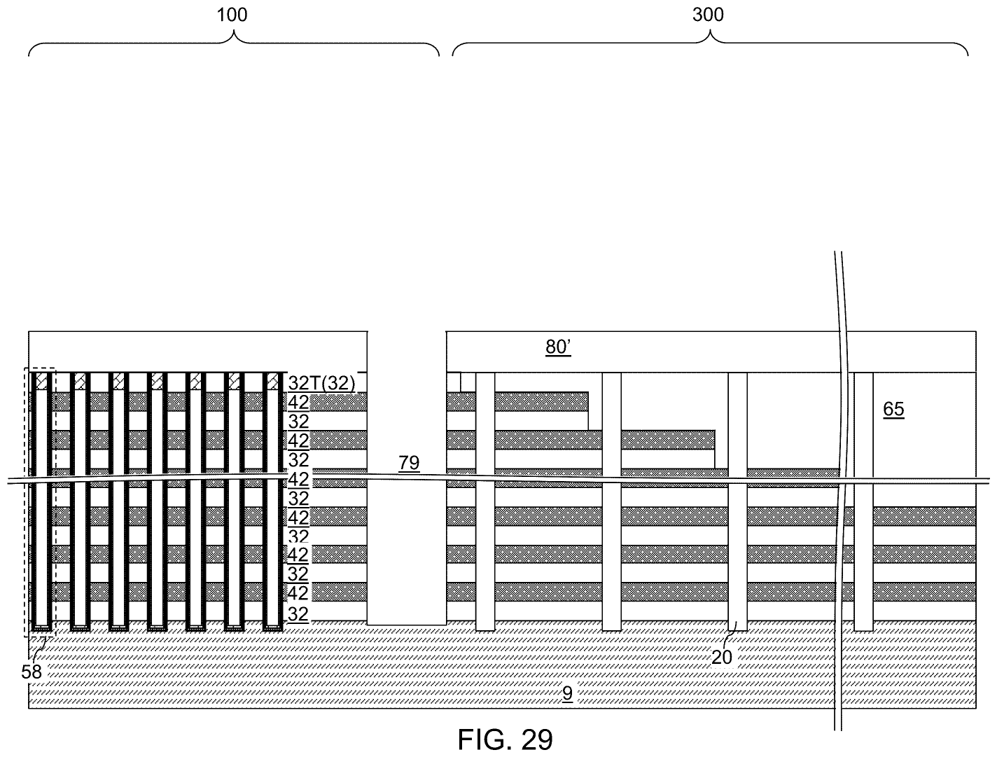

Referring to FIG. 29, a second exemplary structure according to a second embodiment of the present disclosure can be derived from the first exemplary structure illustrated in FIGS. 9A and 9B by forming an in-process contact-level dielectric material layer 80′ in lieu of the layer stack (81, 80) including a contact-level etch-stop dielectric layer 81 and a primary contact-level dielectric layer 80, and by forming the lateral isolation trenches 79. The in-process contact-level dielectric material layer 80′ may have the same material composition as the primary contact-level dielectric layer 80 in the first exemplary structure. The thickness of the in-process contact-level dielectric material layer 80′ may be in a range from 100 nm to 600 nm, although lesser and greater thicknesses may also be employed. The pattern of the lateral isolation trenches 79 may be the same as in the first exemplary structure.

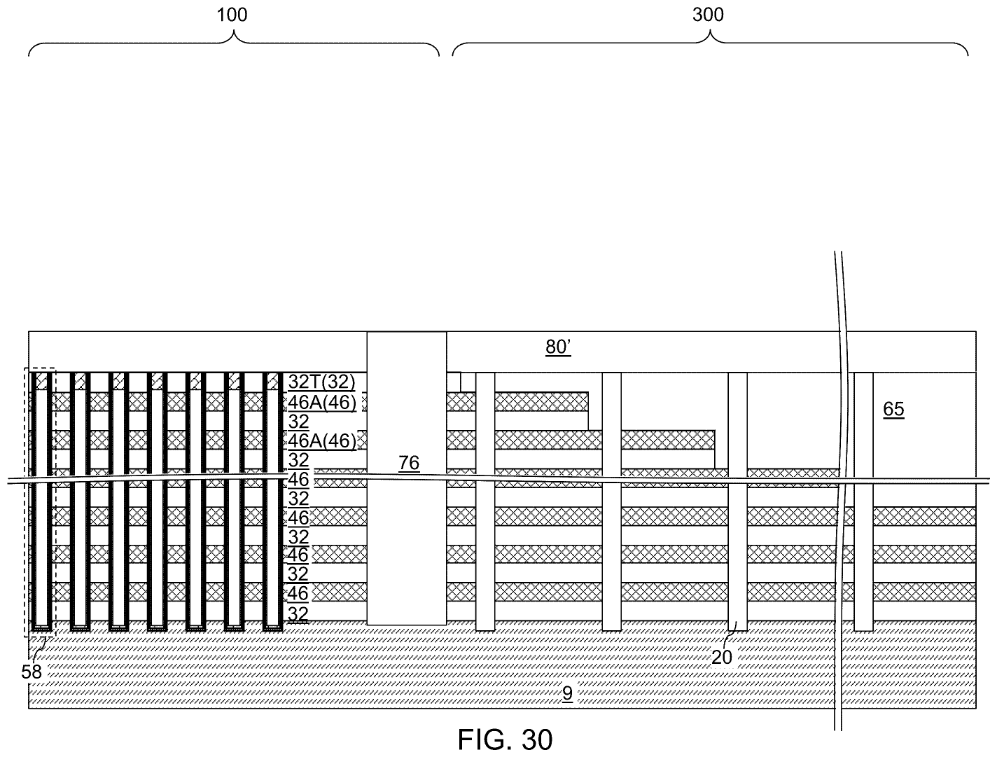

Referring to FIG. 30, the processing steps described with reference to FIGS. 10, 11, and 12 can be performed to replace the sacrificial material layer 42 with electrically conductive layers 46, and to form lateral isolation trench fill structures 76 in the lateral isolation trenches 79.

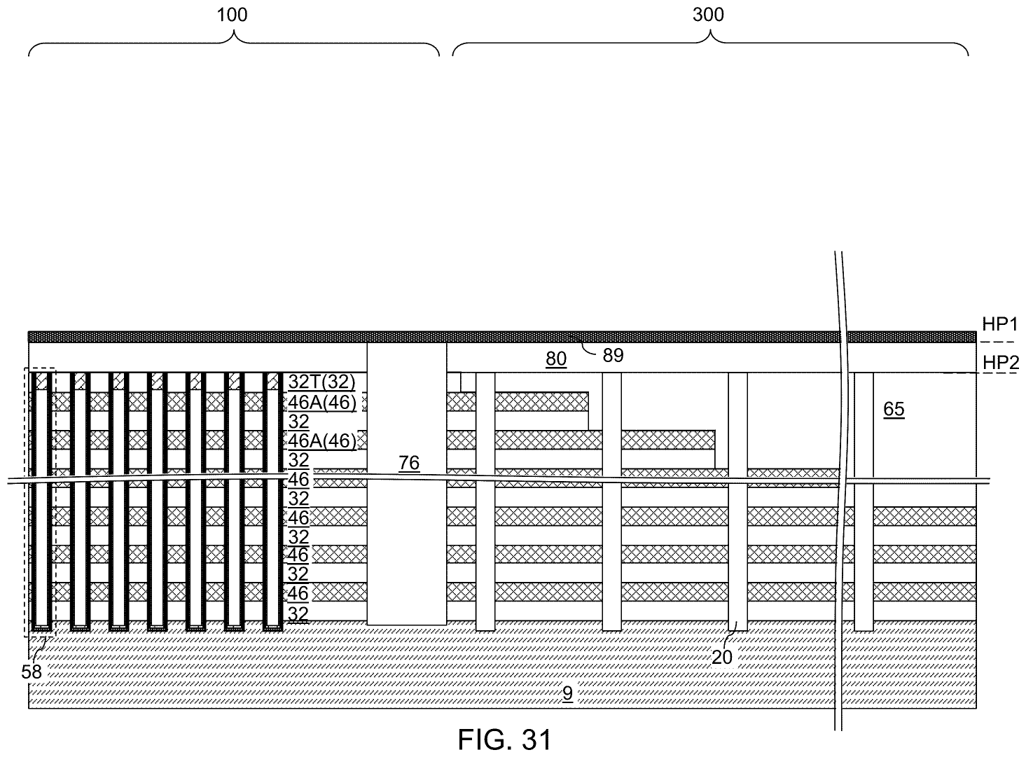

Referring to FIG. 31, an ion implantation process can be performed to implant carbon atoms into an upper portion of the in-process contact-level dielectric material layer 80′. In one embodiment, the in-process contact-level dielectric material layer 80′ comprises silicon oxide, and the implanted upper portion of the in-process contact-level dielectric material layer 80′ comprises silicon oxycarbide. The implanted portion of the in-process contact-level dielectric material layer 80′ subsequently functions as an etch-stop layer, and thus, is hereafter referred to as a contact-level etch-stop dielectric layer 89. The unimplanted portion of the in-process contact-level dielectric material layer 80′ is herein referred to as primary contact-level dielectric layer 80. Thus, the in-process contact-level dielectric material layer 80′ is converted into a layer stack (80, 89) including a primary contact-level dielectric layer 80 and a contact-level etch-stop dielectric layer 89. The thickness of the contact-level etch-stop dielectric layer 89 may be in a range from 15 nm to 100 nm, such as from 30 nm to 80 nm, although lesser and greater thicknesses may also be employed.

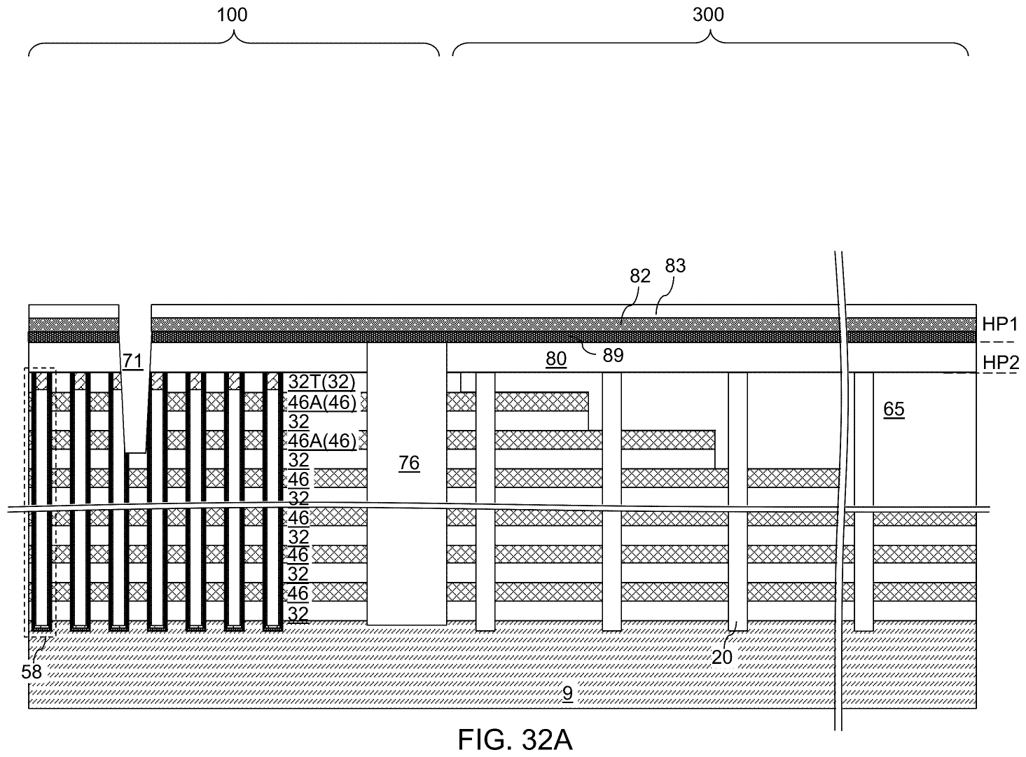

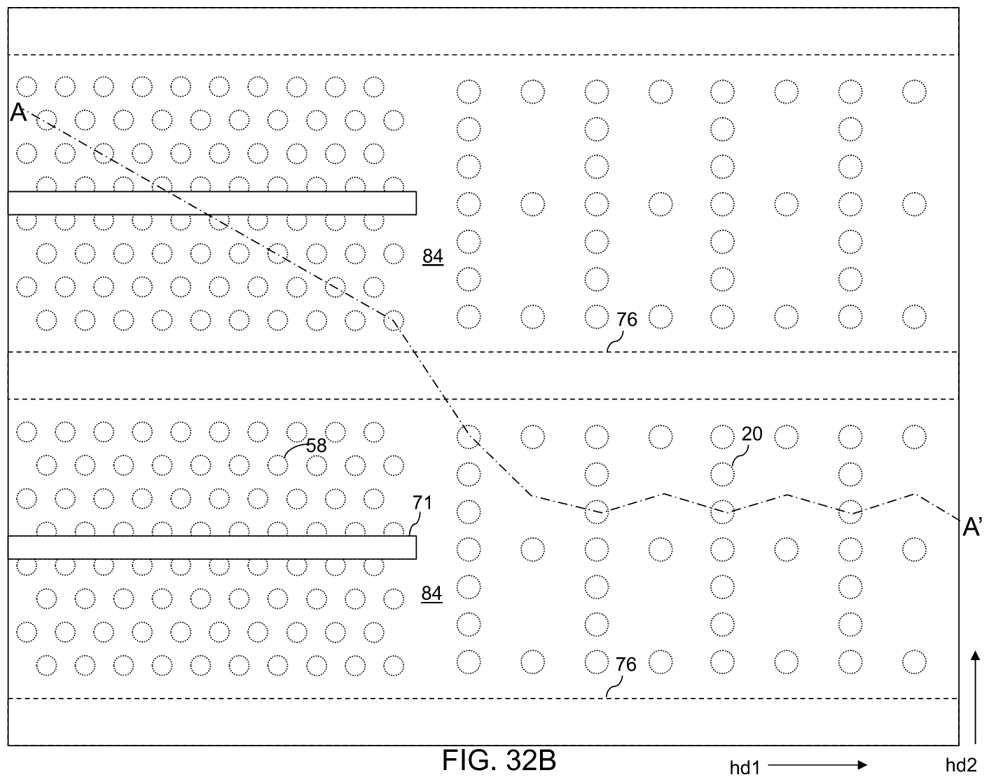

Referring to FIGS. 32A and 32B, a hardmask layer 82 and an optional pad layer 83 can be formed over the layer stack (80, 89). The hard mask layer 82 comprises a hard mask material, such as silicon nitride, and may have a thickness in a range from 10 nm to 80 nm, such as from 20 nm to 60 nm, although lesser and greater thicknesses may also be employed. The optional pad layer 83, if present, may comprise a dielectric pad material such as silicon oxide, and may have a thickness in a range from 5 nm to 80 nm, such as from 10 nm to 60 nm, although lesser and greater thicknesses may also be employed.

A photoresist layer (not shown) can be applied over the hardmask layer 82 and the optional pad layer 83, and can be lithographically patterned to form line-shaped openings laterally extending along the first horizontal direction hd1 in the memory array region 100. The line-shaped openings may have horizontal cross-sectional shapes of an elongated rectangle that laterally extends between a respective neighboring pair of rows of memory opening fill structures 58, i.e., between a first row of memory opening fill structures 58 and a second row of memory opening fill structures 58.

An anisotropic etch process can be performed to transfer the pattern of the openings in the photoresist layer through the optional pad layer 83, the hardmask layer 82, the layer stack (80, 89), through the topmost insulating layer 32T, and through the drain-select-level electrically conductive layer 46A. Lateral isolation cavities 71 having horizontal cross-sectional shapes of elongated rectangles can be formed through the optional pad layer 83, the hardmask layer 82, the layer stack (80, 89), through the topmost insulating layer 32T, and through the drain-select-level electrically conductive layers 46A. Thus, each drain-select-level electrically conductive layer 46A may be divided into a respective plurality of drain-select-level electrically conductive layers 46A (i.e., drain side select gate electrodes) that are laterally spaced apart from each other along the second horizontal direction hd2 (which may be a bit line direction) by at least one lateral isolation cavity 71.

Each lateral isolation cavity 71 may comprise a pair of lengthwise sidewalls having a straight vertical cross-sectional profile, i.e., having a respective straight surface segment in a vertical cross-sectional profile. Each straight surface segment of the lengthwise sidewalls of the lateral isolation cavities 71 may vertically extend from the topmost surface of the optional pad layer 83 and the hardmask layer 82 to a bottom surface of a respective one of the lateral isolation cavities 71. In one embodiment, the memory opening fill structures 58 are arranged in rows that laterally extend generally along a first horizontal direction hd1, sidewalls of two rows of memory opening fill structures 58 may be physically exposed underneath each lateral isolation cavity 71. Each lateral isolation cavity 71 vertically extends through the layer stack (80, 89) and a subset 46A of the electrically conductive layers 46.

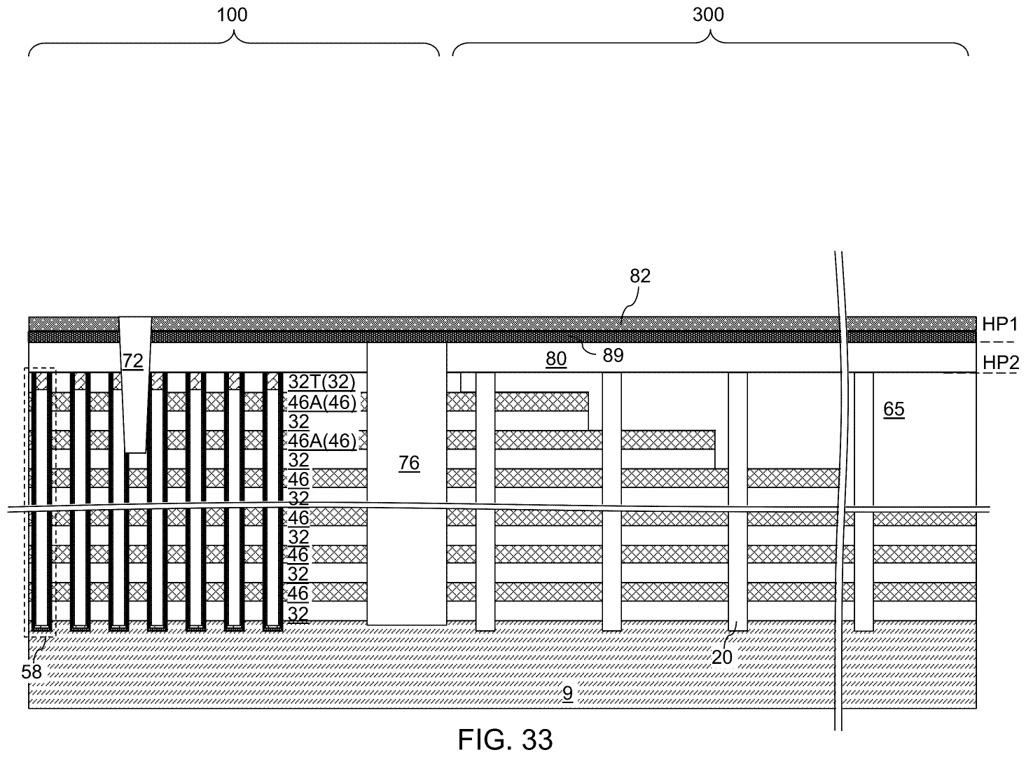

Referring to FIG. 33, the processing steps described with reference to FIG. 14 can be performed to form lateral isolation structures 72 in the lateral isolation cavities 71.

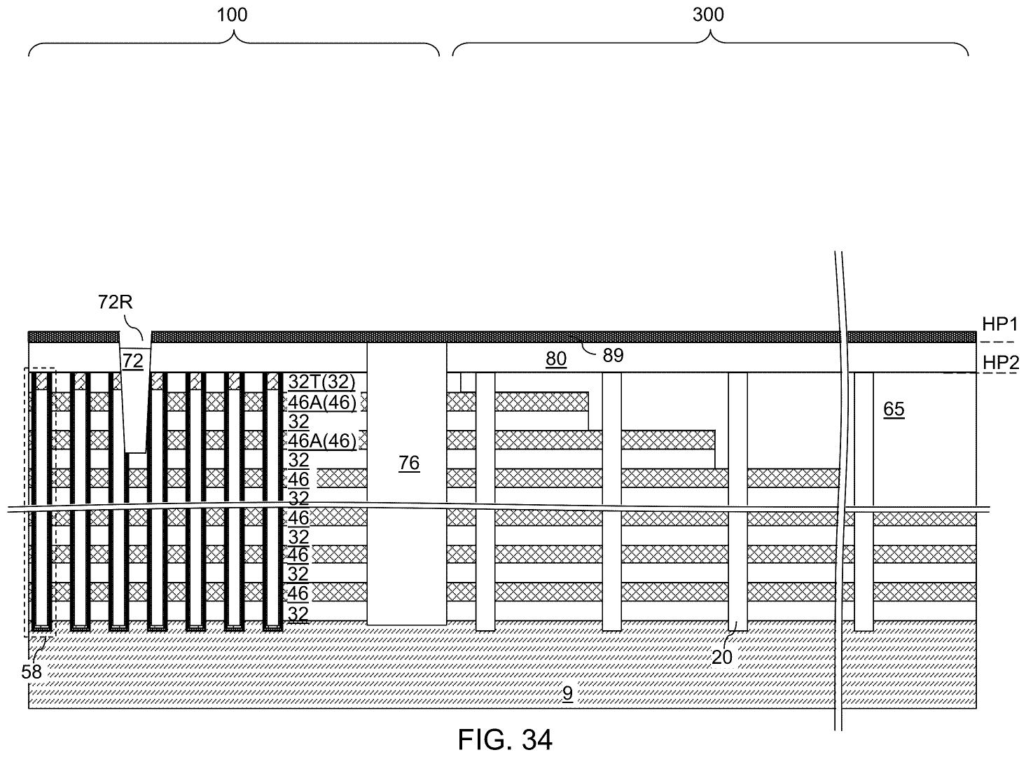

Referring to FIG. 34, the processing steps described with reference to FIG. 15 can be performed to vertically recess the top surfaces of the lateral isolation structures 72 and to form the recesses 72R. The top surfaces of the lateral isolation structures 72 may be formed between the first horizontal plane HP1 including the top surface of the primary contact-level dielectric layer 80 and the second horizontal plane HP2 including the bottom surface of the primary contact-level dielectric layer 80. Subsequently, the processing steps described with reference to FIG. 16 can be performed to remove the hardmask layer 82 selective to the materials of the lateral isolation structures 72 and the contact-level etch-stop dielectric layer 89.

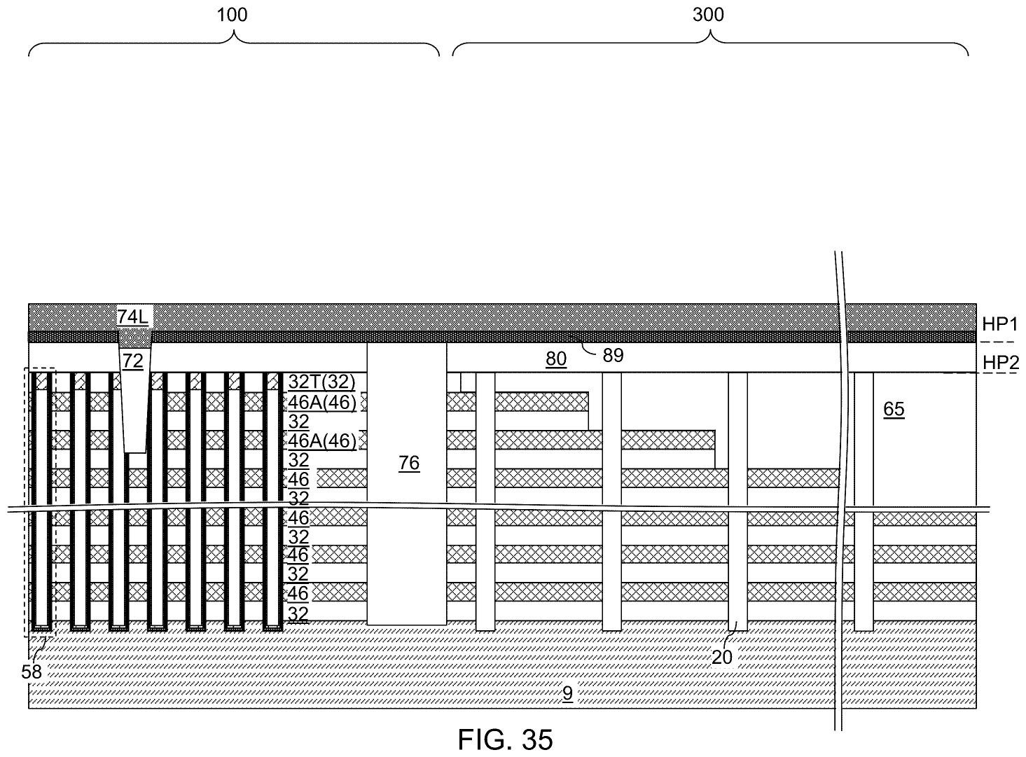

Referring to FIG. 35, the processing steps described with reference to FIG. 17 can be performed to form the etch-stop cap material layer 74L in the recess regions overlying the lateral isolation structures 72 and over the layer stack (80, 89).

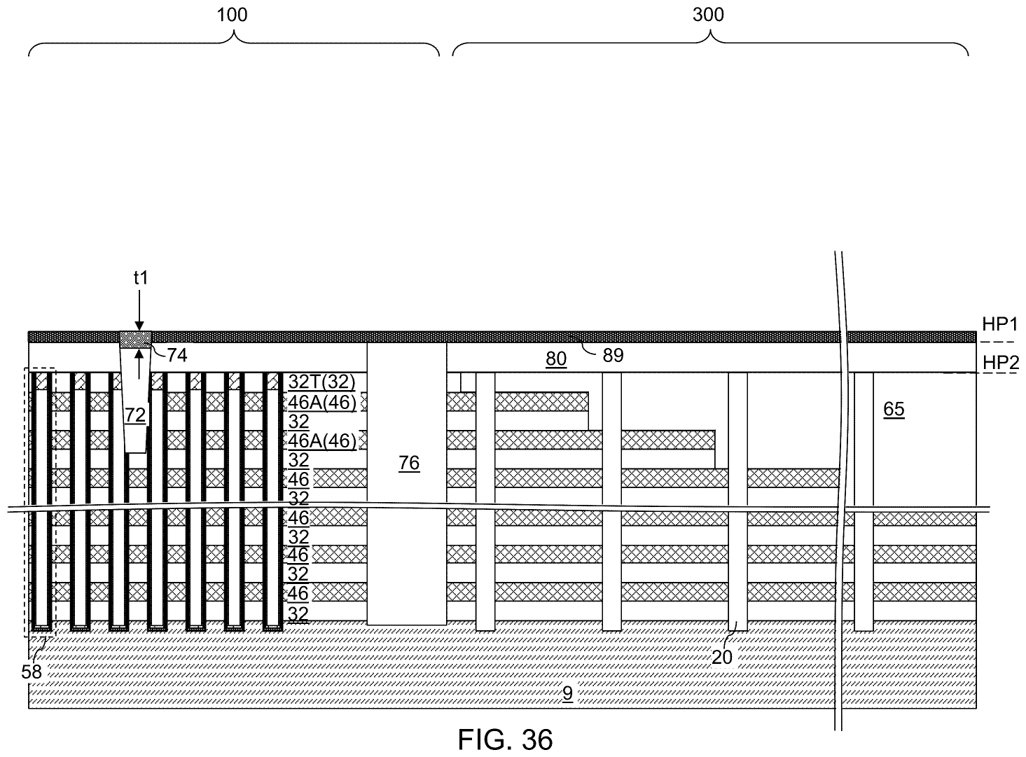

Referring to FIG. 36, the processing steps described with reference to FIG. 18 can be performed to form the etch-stop isolation caps 74. Generally, each etch-stop isolation cap 74 can be formed over a respective lateral isolation structure 72. In one embodiment, an entirety of a bottom periphery of an etch-stop isolation cap 74 may coincide with an entirety of a top periphery of an underlying lateral isolation structure 72. In one embodiment, the top surface of an etch-stop isolation cap 74 may be formed within the first horizontal plane HP1 that includes the top surface of the primary contact-level dielectric layer 80. Each lateral isolation structure 72 vertically extends through a first subset 46A of the electrically conductive layers 46 within the alternating stack (32, 46) and the layer stack (80, 89). In one embodiment, the bottom periphery of the etch-stop isolation cap 74 is located below a first horizontal plane HP1 including a top surface of the primary contact-level dielectric layer 80 and above a second horizontal plane HP2 including a bottom surface of the primary contact-level dielectric layer 80. Each etch-stop isolation cap 74 may have a first thickness t1, which may be in a range from 20 nm to 150 nm, such as from 30 nm to 100 nm, although lesser and greater thicknesses may also be employed.

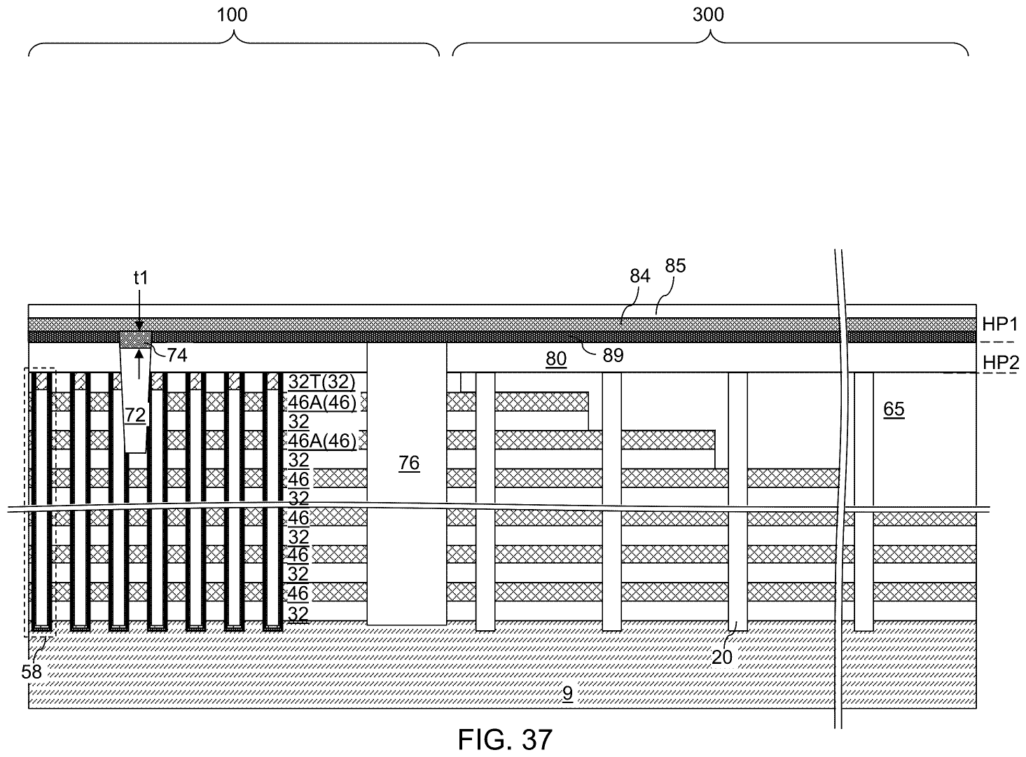

Referring to FIG. 37, at least one contact-level dielectric capping layer (84, 85) can be deposited over the layer stack (80, 89) by performing the processing steps described with reference to FIG. 19. The combination of the layer stack (80, 89) of the primary contact-level dielectric layer 80 and the contact-level etch-stop dielectric layer 89 and the at least one contact-level dielectric capping layer (84, 85) constitutes contact-level dielectric layers (80, 89, 84, 85). In one embodiment, the thickness of the primary contact-level dielectric layer 80 may be at least 50% of the total thickness of the contact-level dielectric layers (80, 89, 84, 85). In one embodiment, each etch-stop isolation cap 74 may have a top surface that contacts a bottom surface of the at least one contact-level dielectric capping layer (84, 85).

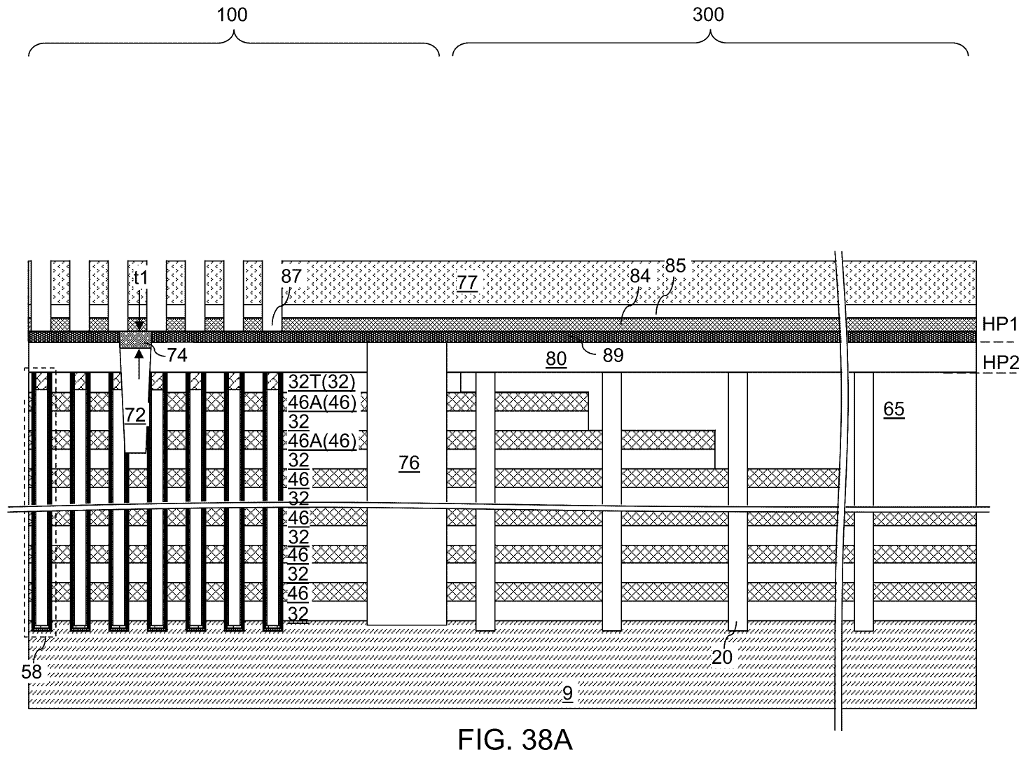

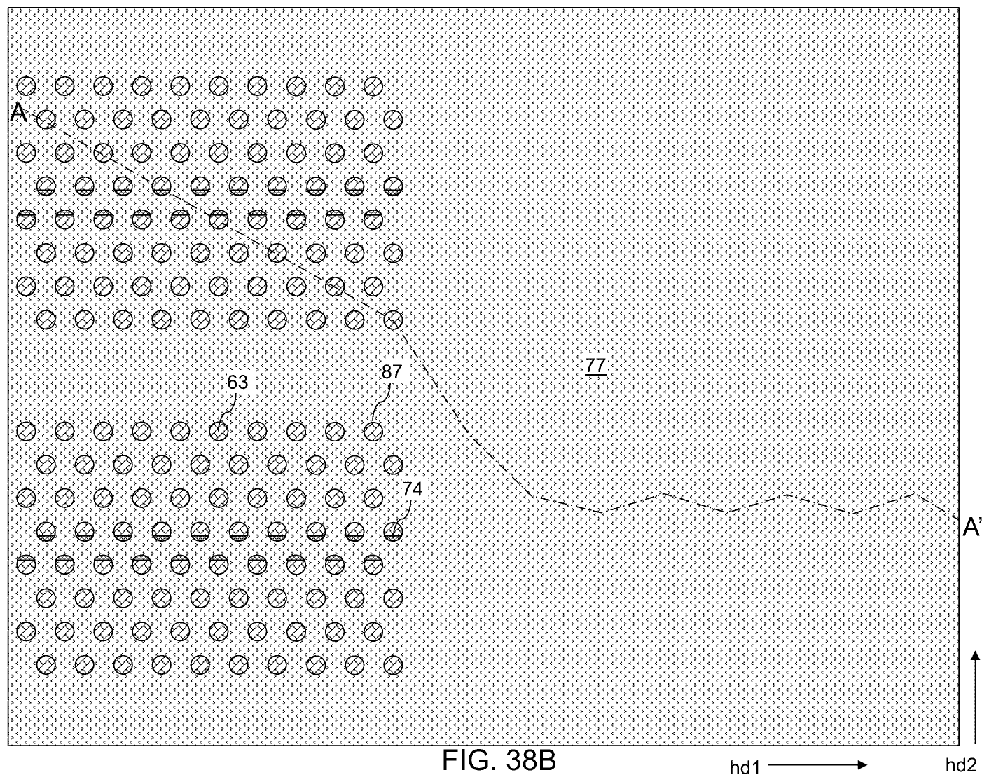

Referring to FIGS. 38A and 38B, a first photoresist layer 77 may be applied over the at least one contact-level dielectric capping layer (84, 85), and can be lithographically patterned with discrete openings having the same pattern as the pattern of the memory opening fill structures 58. An anisotropic etch process can be subsequently performed to transfer the pattern of the openings in the first photoresist layer 77 through the contact-level dielectric layers (80, 89, 84, 85). The anisotropic etch process may comprise a first step that etches unmasked portions of the at least one contact-level dielectric capping layer (84, 85) using the contact-level etch-stop dielectric layer 89 as an etch stop. For example, the first step of the anisotropic etch process may comprise a sequence of a first anisotropic etch phase that etches the material of the second contact-level dielectric capping layer 85 selective to the material of the first contact-level dielectric capping layer 84, and a second anisotropic etch phase that etches the material of the first contact-level dielectric capping layer 84 selective to the material of the etch-stop isolation caps 74 and preferably selective to the material of the contact-level etch-stop dielectric layer 89. In one embodiment shown in FIG. 38B, an etch-stop isolation cap 74 may comprise two rows of physically exposed top surface segments after the first step of the anisotropic etch process. Each physically exposed top surface segment may have a planar shape including an arc segment and a chord segment that is parallel to the first horizontal direction hd1. Drain contact via cavities 87 are formed in volumes from which the materials of the at least one contact-level dielectric capping layer (84, 85) are removed.

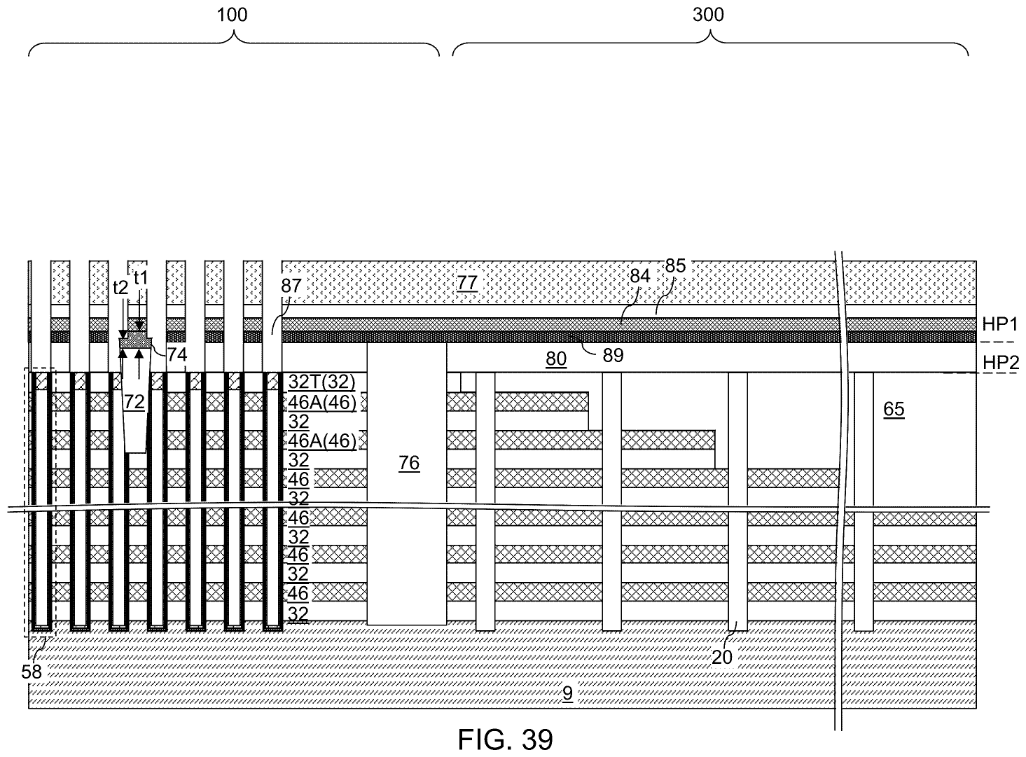

Referring to FIG. 39, a second step of the anisotropic etch process can be performed to etch unmasked portions of the contact-level etch-stop dielectric layer 89 selective to the material of the etch-stop isolation caps 74. Thus, the drain contact via cavities 87 can be vertically extended through the contact-level etch-stop dielectric layer 89. Unmasked top surface segments of the etch-stop isolation caps 74 may be collaterally vertically recessed during the second step of the anisotropic etch process.

A third step of the anisotropic etch process can be performed to etch unmasked portions of the primary contact-level dielectric layer 80 selective to the material of the drain regions 63 and preferably selective to the material of the etch-stop isolation caps 74. In some embodiments, unmasked portions of the etch-stop isolation caps 74 may be collaterally vertically recessed during the third step of the anisotropic etch process. In summary, the various steps of the anisotropic etch process forms drain contact via cavities 87 such that top surfaces of the drain regions 63 are exposed underneath the drain contact via cavities 87 employing etch chemistries that are selective to the material of the etch-stop isolation caps 74. Portions of the etch-stop isolation caps 74 that are located within the areas of the openings in the first photoresist layer 77 can be thinned to a second thickness t2, which is less than the first thickness t1. The second thickness t2 may be in a range from 10% to 95%, such as from 40% to 90%, and/or from 60% to 85%, of the first thickness t1, although lesser and greater ranges may also be employed. The first photoresist layer 77 can be subsequently removed, for example, by ashing.

Therefore, the drain contact via cavities 87 are formed through at least the layer stack (80, 89) by performing an etch process that etches materials of the layer stack (80, 89) selective to the etch-stop isolation caps 74. Top surfaces of the drain regions 63 are exposed underneath the drain contact via cavities 87. The etch-stop isolation caps 74 prevent or reduce etching of the lateral isolation structures 72, and thus prevent or reduce short circuits between the drain contact via structures and the drain side select gate electrodes 46A. Thus, each drain contact via cavity 87 to which an etch-stop isolation cap 74 is exposed may be laterally bounded by a respective lateral isolation structure 72.

In one embodiment, each drain contact via cavity 87 that is laterally bounded by a lateral isolation structure 72 (i.e., having a sidewall that is a surface of the lateral isolation structure 72) may have a respective vertical cross-sectional profile having a respective stepped sidewall. In one embodiment, each stepped sidewall of the vertical cross-sectional profiles has an upper vertically-extending surface segment, a lower vertically-extending surface segment, and a horizontal connecting surface segment that connects the upper vertically-extending surface segment and the lower vertically-extending surface segment. In one embodiment, for each stepped sidewall of the vertical cross-sectional profiles, the upper vertically-extending surface segment comprises a sidewall surface segment of the at least one contact-level dielectric capping layer (84, 85) and a first sidewall segment of etch-stop isolation cap 74. The lower vertically-extending surface segment comprises a second sidewall segment of the etch-stop isolation cap 74 and optionally a sidewall segment of lateral isolation structure 72. The horizontal connecting surface segment comprises a horizontal surface segment of etch-stop isolation cap 74.

In one embodiment, each etch-stop isolation cap 74 has a first thickness t1 in a continuous area that does not have any areal overlap with the openings in the first photoresist layer 77 in a plan view, and has a second thickness t2 in discrete areas having an areal overlap with a respective one of the openings in the first photoresist layer 77 in the plan view. The second thickness t2 is less than the first thickness t1.

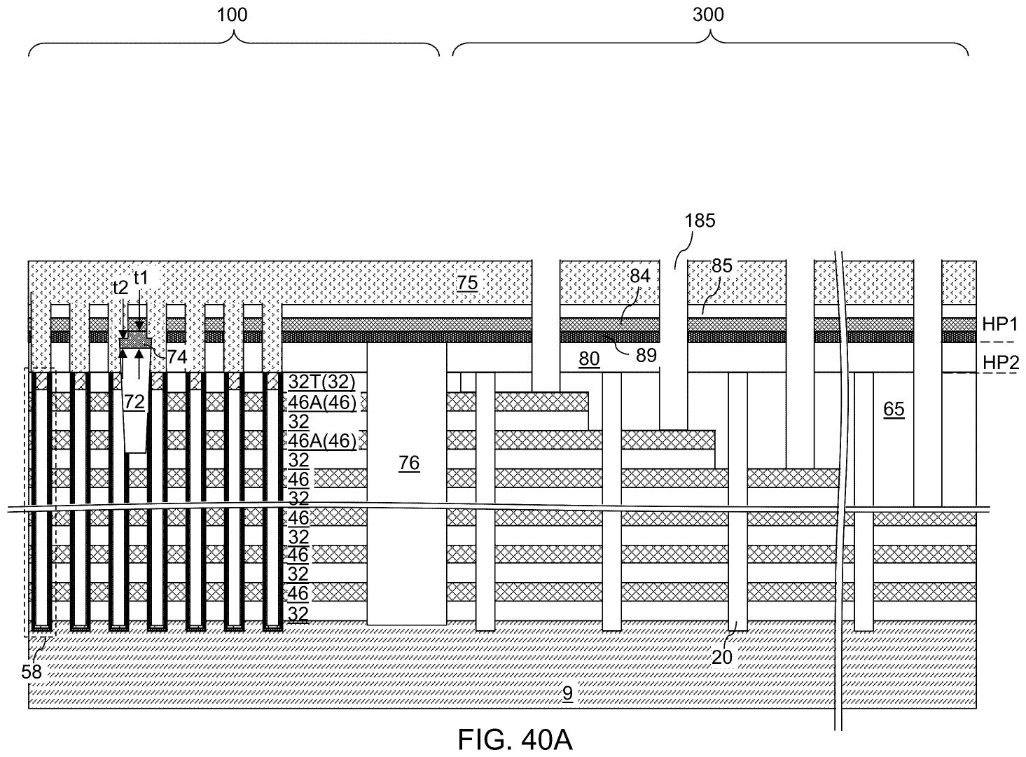

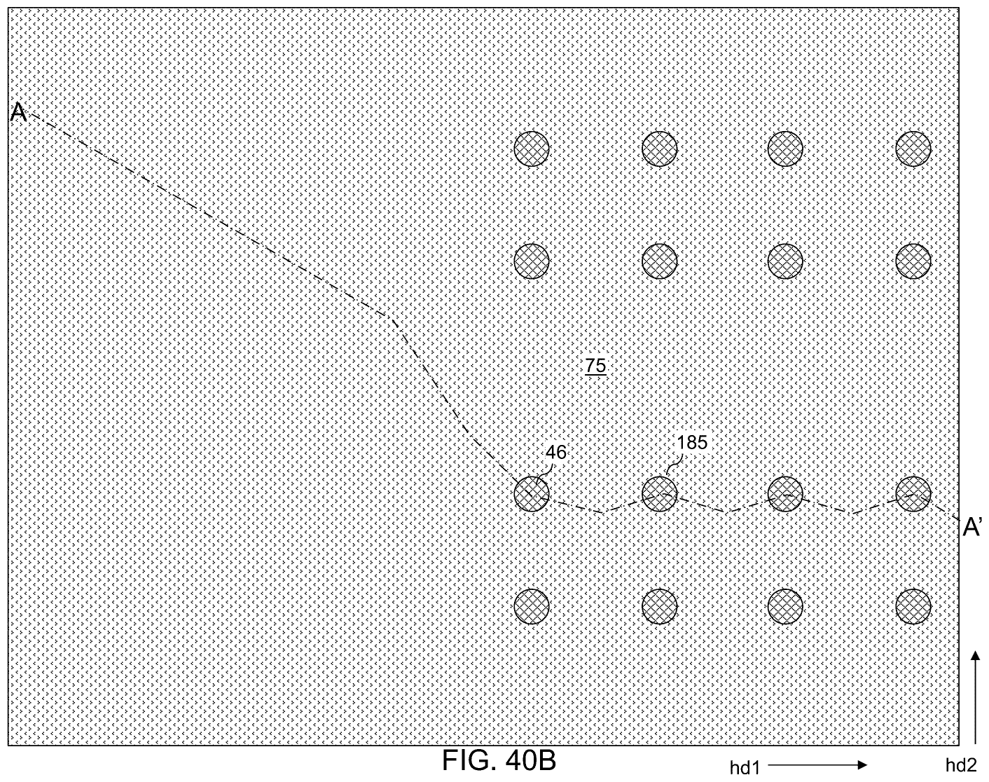

Referring to FIGS. 40A and 40B, a second photoresist layer 75 can be applied over the at least one contact-level dielectric capping layer (84, 85), and can be lithographically patterned to form openings in areas in the contact region 300 that overlies a respective horizontally-extending surface segment of the electrically conductive layers 46. An anisotropic etch process can be performed to transfer the pattern of the openings in the second photoresist layer 75 through the at least one contact-level dielectric capping layer (84, 85), the contact-level etch-stop dielectric layer 89, the primary contact-level dielectric layer 80, and the stepped dielectric material portion 65. Layer contact via cavities 185 can be formed through the at least one contact-level dielectric capping layer (84, 85), the contact-level etch-stop dielectric layer 89, the primary contact-level dielectric layer 80, and the stepped dielectric material portion 65 on a top surface of a respective one of the electrically conductive layers 46. Each electrically conductive layer 46 may have a top surface segment that is exposed to a respective overlying layer contact via cavity 185. The second photoresist layer 75 can be subsequently removed, for example, by ashing. Alternatively, the cavities 87 and 185 may be formed during the same photolithography and etching steps.

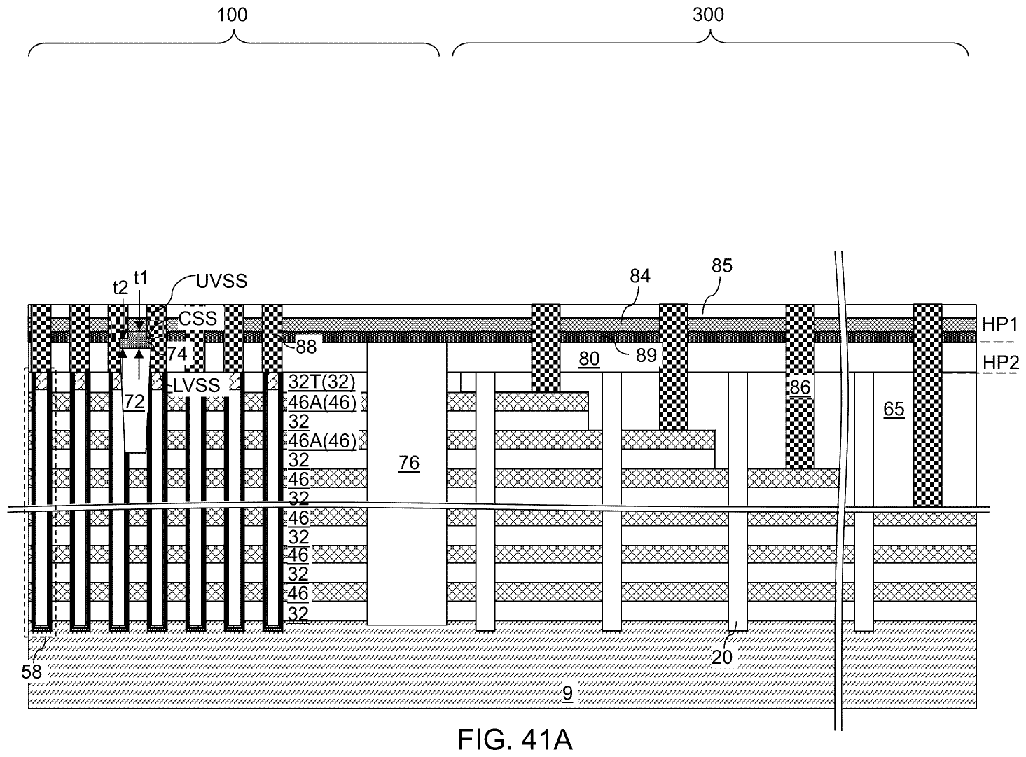

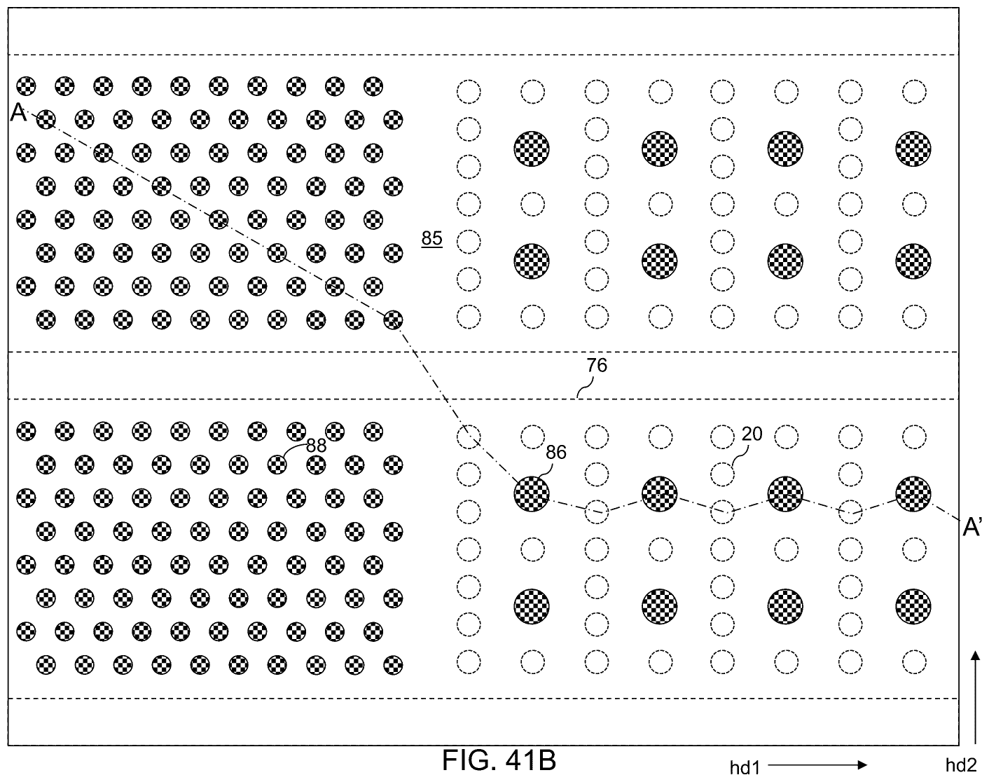

Referring to FIGS. 41A and 41B, at least one metallic material can be deposited in the drain contact via cavities 87 and the layer contact via cavities 185. The at least one metallic material may comprise a metallic barrier material (such as TiN, TaN, WN, and/or MoN) and a metal fill material (such as W, Ru, Co, Mo, Cu, etc.). Excess portions of the at least one metallic material can be removed from above the horizontal plane including the topmost surface of the at least one contact-level dielectric capping layer (84, 85). Each remaining portion of the at least one metallic material that fills a drain contact via cavity 87 comprises drain contact via structure 88. Each remaining portion of the at least one metallic material that fills a layer contact via cavity 185 comprises a layer contact via structure 86.

Each of the drain contact via structures 88 vertically extends through the contact-level dielectric layers (80, 89, 84, 85) and contacts a top surface of a respective drain region 63. A first subset of the drain contact via structures 88 has a respective vertical cross-sectional profile having a respective stepped sidewall that contacts a respective lateral isolation structure 72. Each stepped sidewall of the vertical cross-sectional profiles has an upper vertically-extending surface segment UVSS, a lower vertically-extending surface segment LVSS, and a connecting surface segment CSS that connects the upper vertically-extending surface segment UVSS and the lower vertically-extending surface segment LVSS.

In one embodiment, for each stepped sidewall of the vertical cross-sectional profiles, the upper vertically-extending surface segment UVSS contacts a sidewall surface segment of the at least one contact-level dielectric capping layer (84, 85) and a first sidewall segment of etch-stop isolation cap 74 and/or a sidewall of the silicon oxycarbide contact-level etch-stop dielectric layer 89. The lower vertically-extending surface segment LVSS contacts a second sidewall segment of the etch-stop isolation cap 74 and a sidewall segment of lateral isolation structure 72. The horizontal connecting surface segment CSS contacts a horizontal surface segment of etch-stop isolation cap 74.

All sidewalls of a second subset of the drain contact via structures 88 may be straight, and may vertically extend from a topmost surface of the contact-level dielectric layers (80, 89, 84, 85) to a bottommost surface of the contact-level dielectric layers (80, 89, 84, 85). The second subset of the drain contact via structures 88 is not in contact with any of the lateral isolation structures 72.

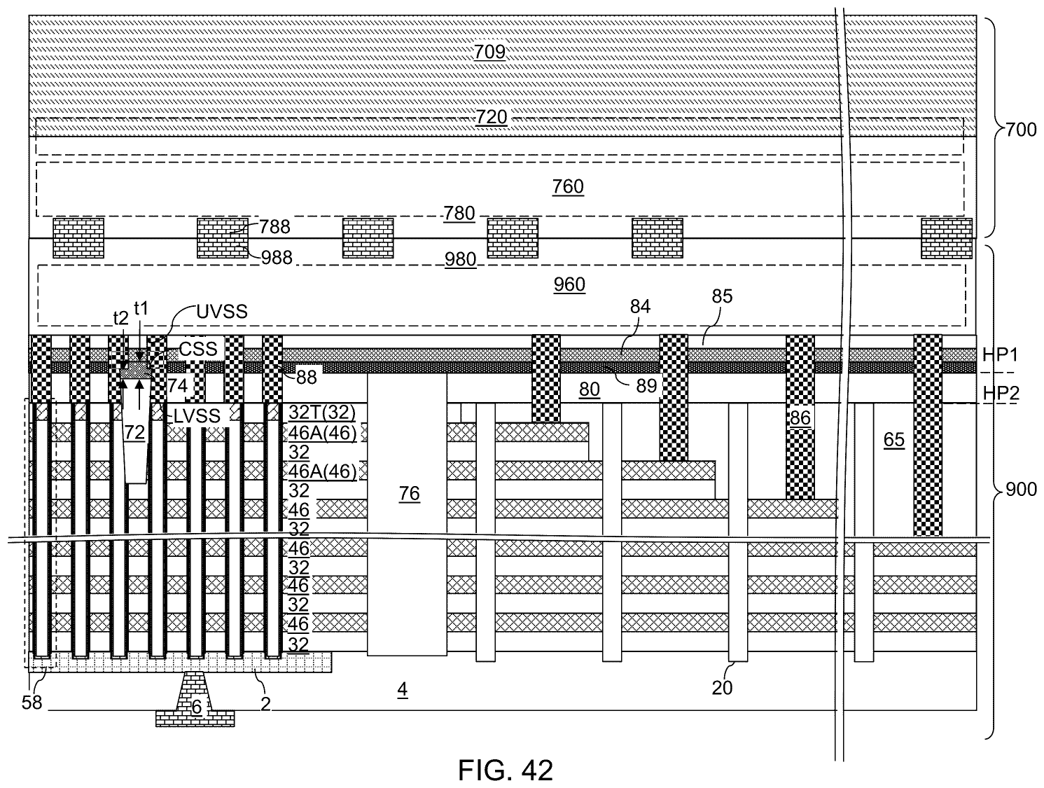

Referring to FIG. 42, the processing steps described with respect to FIG. 25 can be performed to provide a memory die 900. The processing steps described with respect to FIGS. 26 and 27 can be performed to bond a logic die 700 to the memory die 900. The processing steps described with respect to FIG. 28 can be performed to remove the carrier substrate 9 and bottom end portions of the memory films 50, and to form a source layer 2 and backside contact structures 6.

Referring to all drawings and according to various embodiments of the present disclosure, a three-dimensional memory device is provided, which comprises: an alternating stack (32, 46) of insulating layers 32 and electrically conductive layers 46; memory openings 49 vertically extending through the alternating stack (32, 46); memory opening fill structures 58 located in the memory openings 49, wherein each of the memory opening fill structures 58 comprises a respective vertical semiconductor channel 60, a respective vertical stack of memory elements (which may comprise portions of a memory material layer 54 located at levels of the electrically conductive layers 46), and a respective drain region 63; contact-level dielectric layers {(81 or 89), 80, 84, 85} overlying the alternating stack (32, 46); a lateral isolation structure 72 vertically extending through a first subset of the electrically conductive layers 46 within the alternating stack (32, 46) and a first subset of the contact-level dielectric layers {(81 or 89), 80, 84, 85}; an etch-stop isolation cap 74 overlying the lateral isolation structure 72; and drain contact via structures 88 vertically extending through the contact-level dielectric layers {(81 or 89), 80, 84, 85} and contacting top surfaces of the drain regions 63.

In one embodiment, the contact-level dielectric layers {(81 or 89), 80, 84, 85} comprise a primary contact-level dielectric layer 80 and a contact-level etch-stop dielectric layer (81 or 89). In one embodiment, at least one contact-level dielectric capping layer (84, 85) overlies the primary contact-level dielectric layer 80 and the contact-level etch-stop dielectric layer (81 or 89). A top surface of the etch-stop isolation cap 74 contacts a bottom surface of the at least one contact-level dielectric capping layer (84, 85).

In one embodiment, a subset of the drain contact via structures 88 has a respective vertical cross-sectional profile having a respective stepped sidewall that contacts the lateral isolation structure 72, wherein each stepped sidewall of the vertical cross-sectional profiles has an upper vertically-extending surface segment UVSS, a lower vertically-extending surface segment LVSS, and a connecting surface segment CSS that connects the upper vertically-extending surface segment UVSS and the lower vertically-extending surface segment LVSS.

In one embodiment, for each stepped sidewall of the vertical cross-sectional profiles, the upper vertically-extending surface segment UVSS contacts a sidewall surface segment of the at least one contact-level dielectric capping layer (84, 85) and a first sidewall segment of etch-stop isolation cap 74, the lower vertically-extending surface segment LVSS contacts a second sidewall segment of the etch-stop isolation cap 74 and a sidewall segment of lateral isolation structure 72, and the connecting surface segment CSS contacts a horizontal surface segment of etch-stop isolation cap 74.

In one embodiment, the etch-stop isolation cap 74 has a first thickness t1 in a continuous area that does not have any areal overlap with the drain contact via structures 88 in a plan view, and has a second thickness t2 in discrete areas having an areal overlap with a respective one of the drain contact via structures 88, the second thickness t2 being less than the first thickness t1. In one embodiment, an entirety of a bottom periphery of the etch-stop isolation cap 74 coincides with an entirety of a top periphery of the lateral isolation structure 72. In one embodiment, the bottom periphery of the etch-stop isolation cap 74 is located below a first horizontal plane HP1 including a top surface of the primary contact-level dielectric layer 80 and above a second horizontal plane HP2 including a bottom surface of the primary contact-level dielectric layer 80. In one embodiment, the memory opening fill structures 58 are arranged in rows that laterally extend generally along a first horizontal direction hd1; and the lateral isolation structure 72 is in contact with sidewalls of two rows of the memory opening fill structures 58.

In one embodiment, the primary contact-level dielectric layer 80 overlies the contact-level etch-stop dielectric layer 81, which comprises silicon carbonitride. In one embodiment, a top surface of the lateral isolation structure 72 is located within a horizontal plane including a top surface of the primary contact-level dielectric layer 80.

In one embodiment, the contact-level etch-stop dielectric layer 89 comprises silicon oxycarbide and overlies the primary contact-level dielectric layer 80. In one embodiment, a top surface of the lateral isolation structure 72 is located within a horizontal plane including a top surface of the contact-level etch-stop dielectric layer 89.

The etch-stop isolation caps 74 and the etch-stop dielectric layers (81, 89) reduce or prevent vertical overextension of drain contact via cavities 87 along sidewalls of drain regions 63 to topmost drain-select-level electrically conductive layers 46A. Thus, the etch-stop isolation caps 74 and the etch-stop dielectric layers prevent or reduce electrical shorts between the drain contact via structures 88 and the drain-select-level electrically conductive layers 46A, and increase the reliability of a three-dimensional memory device.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
an alternating stack of insulating layers and electrically conductive layers;
memory openings vertically extending through the alternating stack;
memory opening fill structures located in the memory openings, wherein each of the memory opening fill structures comprises a respective vertical semiconductor channel, a respective vertical stack of memory elements, and a respective drain region;
contact-level dielectric layers overlying the alternating stack;
a lateral isolation structure vertically extending through a first subset of the electrically conductive layers within the alternating stack and a first subset of the contact-level dielectric layers;
an etch-stop isolation cap overlying the lateral isolation structure; and
drain contact via structures vertically extending through the contact-level dielectric layers and contacting top surfaces of the drain regions,

2. The three-dimensional memory device of claim 1, wherein the contact-level dielectric layers comprise a primary contact-level dielectric layer and a contact-level etch-stop dielectric layer.

3. The three-dimensional memory device of claim 2, wherein a subset of the drain contact via structures has a respective vertical cross-sectional profile having a respective stepped sidewall that contacts the lateral isolation structure, wherein each stepped sidewall of the vertical cross-sectional profiles has an upper vertically-extending surface segment, a lower vertically-extending surface segment, and a connecting surface segment that connects the upper vertically-extending surface segment and the lower vertically-extending surface segment.

4. The three-dimensional memory device of claim 3, further comprising at least one contact-level dielectric capping layer overlying the primary contact-level dielectric layer and the contact-level etch-stop dielectric layer, wherein a top surface of the etch-stop isolation cap contacts a bottom surface of the at least one contact-level dielectric capping layer.

5. The three-dimensional memory device of claim 4, wherein:
the upper vertically-extending surface segment contacts a sidewall surface segment of the at least one contact-level dielectric capping layer and a first sidewall segment of etch-stop isolation cap;
the lower vertically-extending surface segment contacts a second sidewall segment of the etch-stop isolation cap and a sidewall segment of lateral isolation structure; and
the connecting surface segment contacts a horizontal surface segment of etch-stop isolation cap.

6. The three-dimensional memory device of claim 2, wherein:
an entirety of a bottom periphery of the etch-stop isolation cap coincides with an entirety of a top periphery of the lateral isolation structure; and
the bottom periphery of the etch-stop isolation cap is located below a first horizontal plane including a top surface of the primary contact-level dielectric layer and above a second horizontal plane including a bottom surface of the primary contact-level dielectric layer.

7. The three-dimensional memory device of claim 2, wherein the primary contact-level dielectric layer overlies the contact-level etch-stop dielectric layer.

8. The three-dimensional memory device of claim 7, wherein a top surface of the lateral isolation structure is located within a horizontal plane including a top surface of the primary contact-level dielectric layer.

9. The three-dimensional memory device of claim 7, wherein the contact-level etch-stop dielectric layer comprises silicon carbonitride.

10. The three-dimensional memory device of claim 2, wherein the contact-level etch-stop dielectric layer overlies the primary contact-level dielectric layer.

11. The three-dimensional memory device of claim 10, wherein a top surface of the lateral isolation structure is located within a horizontal plane including a top surface of the contact-level etch-stop dielectric layer.

12. The three-dimensional memory device of claim 2, wherein the contact-level etch-stop dielectric layer comprises silicon oxycarbide.

13. The three-dimensional memory device of claim 1, wherein:
the memory opening fill structures are arranged in rows that laterally extend generally along a first horizontal direction; and
the lateral isolation structure is in contact with sidewalls of two rows of the memory opening fill structures.

14. The three-dimensional memory device of claim 1, wherein the etch-stop isolation cap has a first thickness in a continuous area that does not have any areal overlap with the drain contact via structures in a plan view, and has a second thickness in discrete areas having an areal overlap with a respective one of the drain contact via structures, the second thickness being less than the first thickness.

15. A method of forming a three-dimensional memory device, comprising:
forming an assembly of an alternating stack and memory opening fill structures, wherein the alternating stack comprises a vertically alternating sequence of insulating layers and electrically conductive layers, the memory opening fill structures vertically extend through the alternating stack, and each of the memory opening fill structures comprises a respective vertical stack of memory elements, a respective vertical semiconductor channel, and a respective drain region;
forming a layer stack including a primary contact-level dielectric layer and a contact-level etch-stop dielectric layer over the alternating stack;
forming a lateral isolation structure through the layer stack and a subset of the electrically conductive layers;
forming an etch-stop isolation cap over the lateral isolation structure;
forming drain contact via cavities through at least the layer stack by performing an etch process that etches materials of the layer stack selective to the etch-stop isolation cap, wherein top surfaces of the drain regions are exposed underneath the drain contact via cavities; and
forming drain contact via structures in the drain contact via cavities.

16. The method of claim 15, further comprising:
forming a lateral isolation cavity through the layer stack and the subset of the electrically conductive layers;
depositing a dielectric fill material in the lateral isolation cavity; and
vertically recessing the dielectric fill material below a horizontal plane including a top surface of the layer stack to form a recess, wherein a remaining portion of the dielectric fill material comprises the lateral isolation structure.

17. The method of claim 16, further comprising:
depositing an etch-stop cap material in the recess overlying the lateral isolation structure; and
removing portions of the etch-stop dielectric material from above a horizonal plane including a top surface of the layer stack, wherein a remaining portion of the etch-stop dielectric material comprise the etch-stop isolation cap.

18. The method of claim 15, further comprising forming at least one contact-level dielectric capping layer over the layer stack, wherein the drain contact via cavities are formed through the at least one contact-level dielectric capping layer.

19. The method of claim 15, wherein the primary contact-level dielectric layer is formed over the contact-level etch-stop dielectric layer which comprises silicon carbonitride.

20. The method of claim 15, further comprising:
forming an in-process contact-level dielectric material layer over the memory opening fill structures; and
implanting carbon atoms into an upper portion of the in-process contact-level dielectric material layer, wherein an unimplanted portion of the in-process contact-level dielectric layer comprises the primary contact-level dielectric layer, and an implanted underlying portion of the in-process contact-level dielectric layer comprises the contact-level etch-stop dielectric layer which comprises silicon oxycarbide.
